(19) United States
(12) Patent Application Publication
(10) Pub. No.: US 2024/0363667 A1
(43) Pub. Date: Oct. 31, 2024

(54) PHOTOELECTRIC CONVERSION APPARATUS, PHOTOELECTRIC CONVERSION SYSTEM, AND MOVING BODY

(71) Applicant: CANON KABUSHIKI KAISHA, Tokyo (JP)

(72) Inventors: YASUHARU OTA, Tokyo (JP); TOMOYA SASAGO, Kanagawa (JP)

(21) Appl. No.: 18/760,977

(22) Filed: Jul. 1, 2024

Related U.S. Application Data
(63) Continuation of application No. PCT/JP2022/000058, filed on Jan. 5, 2022.

(51) Int. Cl. H01L 27/146; H04N 25/705; H04N 25/766

(52) U.S. Cl. CPC H01L 27/14636; H01L 27/14645; H04N 25/705; H04N 25/766

(57) ABSTRACT

A photoelectric conversion apparatus includes a first substrate and a second substrate. A plurality of wiring layers of a second wiring structure includes a wiring layer where first wiring for supplying a power supply voltage to a plurality of pixel circuits is disposed and an area occupied by the first wiring is the largest among the plurality of wiring layers, and a wiring layer group where the first wiring is disposed, the wiring layer group being located between the wiring layer where the area and a second semiconductor layer. In a plan view, the first wiring is configured to connect both ends of a region in a first direction and both ends of the region in a second direction intersecting the first direction by combination of the wiring layer group, the region including each of the plurality of pixel circuits.

### CROSS-REFERENCE TO RELATED APPLICATIONS

This application is a Continuation of International Patent Application No. PCT/JP2022/000058, filed Jan. 5, 2022, which is hereby incorporated by reference herein in its entirety.

### BACKGROUND OF THE INVENTION

### Field of the Invention

The present invention relates to a photoelectric conversion apparatus, a photoelectric conversion system, and a moving body.

### Background Art

A photoelectric conversion apparatus including a pixel array configured such that a plurality of pixels each including an avalanche photodiode (APD) is arranged in a two-dimensional array on a plane has been known. In each pixel, a reverse bias voltage is applied to the PN junction diode to cause avalanche multiplication of photocharges resulting from a single photon. There are at least two modes of APD operation: a Geiger mode and a linear mode. In the Geiger mode, the APD supplied with a reverse bias voltage operates with a potential difference between the anode and the cathode greater than the breakdown voltage. In the linear mode, the APD operates with the potential difference between the anode and the cathode near the breakdown voltage or less than or equal to the breakdown voltage. APDs operating in the Geiger mode are referred to as single photon avalanche diodes (SPADs).

PTL 1 discusses an SPAD sensor including a first substrate and a second substrate stacked on each other, where APDs are disposed on the first substrate and signal processing circuits for processing signals from the APDs are disposed on the second substrate. PTL 1 also discusses a counter circuit for counting the number of incident photons.

### CITATION LIST

### Patent Literature

PTL 1: Japanese Patent Application Laid-Open No. 2019-158806

APD sensors include a large number of circuits per pixel and a large number of power supply lines to the circuits and input/output lines to/from the circuits, and thus have a high wiring density compared to complementary metal-oxide-semiconductor (CMOS) sensors. However, PTL 1 does not discuss a wiring configuration for solving issues resulting from a high wiring density of an APD sensor.

### SUMMARY OF THE INVENTION

The present invention is directed to proposing a wiring configuration for solving issues resulting from a high wiring density of an avalanche photodiode (APD) sensor.

According to an aspect of the present invention, a photoelectric conversion apparatus includes a first substrate including a first semiconductor layer and a first wiring structure, the first semiconductor layer including a plurality of photoelectric conversion units, the first wiring structure including at least one wiring layer, a second substrate including a second semiconductor layer and a second wiring structure, the second semiconductor layer including a plurality of pixel circuits disposed to correspond to each of the plurality of respective photoelectric conversion units, respectively, the second wiring structure including a plurality of wiring layers. Each of the plurality of photoelectric conversion units includes an avalanche photodiode. The first substrate and the second substrate are stacked such that the first wiring structure and the second wiring structure are located between the first semiconductor layer and the second semiconductor layer. The first wiring structure or the second wiring structure includes a pad electrode configured to supply a voltage to the avalanche photodiode. The plurality of wiring layers of the second wiring structure includes a wiring layer where first wiring configured to supply a power supply voltage to the plurality of pixel circuits is disposed and an area occupied by the first wiring is largest among the plurality of wiring layers, and a wiring layer group where the first wiring is disposed, the wiring layer group being located between the wiring layer where the area occupied by the first wiring is the largest among the plurality of wiring layers and the second semiconductor layer. In a plan view, the first wiring is configured to connect both ends of a region in a first direction and both ends of the region in a second direction intersecting the first direction by combination of the wiring layer group, the region including each of the plurality of pixel circuits.

Further features of the present invention will become apparent from the following description of exemplary embodiments with reference to the attached drawings.

### BRIEF DESCRIPTION OF THE DRAWINGS

FIG. 1 is a block diagram of a photoelectric conversion apparatus.

FIG. 2 is a functional block diagram of a first substrate.

FIGS. 3A and 3B are functional block diagrams of a second substrate.

FIG. 4 is a functional block diagram of the first and second substrates.

FIGS. 5A and 5B are diagrams schematically illustrating a relationship between the operation of an avalanche photodiode (APD) and an output signal.

FIG. 6 is a sectional view of the photoelectric conversion apparatus.

FIGS. 7A to 7D are diagrams illustrating a wiring layout of a power supply voltage according to a first exemplary embodiment.

FIGS. 8A to 8E are diagrams illustrating a wiring layout of a power supply voltage according to the first exemplary embodiment.

FIGS. 9A to 9E are diagrams illustrating a wiring layout of a power supply voltage according to the first exemplary embodiment.

FIGS. 10A to 10D are diagrams illustrating a wiring layout of power supply voltages according to a second exemplary embodiment.

FIGS. 11A to 11I are diagrams illustrating a wiring layout of power supply voltages according to the second exemplary embodiment.

FIGS. 12A and 12B are diagrams illustrating a layout of pixel circuits according to a third exemplary embodiment.

FIGS. 13A and 13B are diagrams illustrating a layout of pixel circuits according to the third exemplary embodiment.

FIGS. 14A and 14B are diagrams illustrating a layout of pixel circuits according to a fourth exemplary embodiment.

FIGS. 15A to 15C are diagrams illustrating a layout of pixel circuits according to the fourth exemplary embodiment.

FIGS. 16A to 16C are diagrams illustrating a configuration and wiring layout of a photoelectric conversion apparatus according to a fifth exemplary embodiment.

FIG. 17A to 17C are diagrams illustrating a configuration and wiring layout of a photoelectric conversion apparatus according to a sixth exemplary embodiment.

FIG. 18 is a sectional view of a first modification of a photoelectric conversion apparatus.

FIG. 19 is a sectional view of a second modification of a photoelectric conversion apparatus.

FIG. 20 is a sectional view of a third modification of a photoelectric conversion apparatus.

FIG. 21 is a sectional view of a fourth modification of a photoelectric conversion apparatus.

FIG. 22 is a functional block diagram of a photoelectric conversion system according to a seventh exemplary embodiment.

FIG. 23 is a functional block diagram of a distance sensor according to an eighth exemplary embodiment.

FIG. 24 is a functional block diagram of an endoscopic surgery system according to a ninth exemplary embodiment.

FIG. 25A is a block diagram illustrating a photoelectric conversion system according to a tenth exemplary embodiment. FIG. 25B is a diagram illustrating a moving body according to the tenth exemplary embodiment.

FIGS. 26A and 26B are diagrams illustrating smart glasses according to an eleventh exemplary embodiment.

### DESCRIPTION OF THE EMBODIMENTS

Exemplary embodiments described below are intended to embody the technical concept of the present invention and not limit the present invention. The sizes and positional relationships of members illustrated in the drawings may be exaggerated for the clarity of description. In the following description, similar components are denoted by the same reference numerals, and a description thereof may be omitted.

The following exemplary embodiments relate to a photoelectric conversion apparatus including single photon avalanche diodes (SPADs) to count the numbers of photons incident on the avalanche diodes in particular. The photoelectric conversion apparatus can include at least avalanche diodes, which may be operated in a linear mode as well as a Geiger mode.

In the following description, the potential at the anode of each avalanche diode is fixed, and a signal is taken out from the cathode. A semiconductor region of a first conductivity type where the majority carrier is a charge of the same conductivity type as that of the signal charge thus refers to an N-type semiconductor region. A semiconductor region of a second conductivity type refers to a P-type semiconductor region. Note that the exemplary embodiments of the present invention also hold if the potential at the cathode of each avalanche diode is fixed and a signal is taken out from the anode. In such a case, a semiconductor region of the first conductivity type where the majority carrier is a charge of the same conductivity type as that of the signal charge refers to a P-type semiconductor region. A semiconductor region of the second conductivity type refers to an N-type semiconductor region. While a case where the potential at one of the nodes of each avalanche diode is fixed will be described below, the potentials at both nodes may be variable.

As employed herein, a plan view refers to a view in a direction perpendicular to the light incident surface of a semiconductor layer. A cross section refers to a section perpendicular to the light incident surface of the semiconductor layer. If the light incident surface of the semiconductor layer is a microscopically rough surface, the plan view is defined with reference to the light incident surface of the semiconductor layer seen macroscopically.

As employed herein, for the sake of convenience, a wiring layer closest to a semiconductor layer may be referred to as a first wiring layer, and a second wiring layer, third wiring layer, and so on may be described in the order of increasing distance from the semiconductor layer. However, in the claims, a “first wiring layer” is not the wiring layer closest to a semiconductor layer and the ordinals do not indicate the order of wiring layers unless otherwise specified in the claims.

### (Overall Block Diagram of Photoelectric Conversion Apparatus)

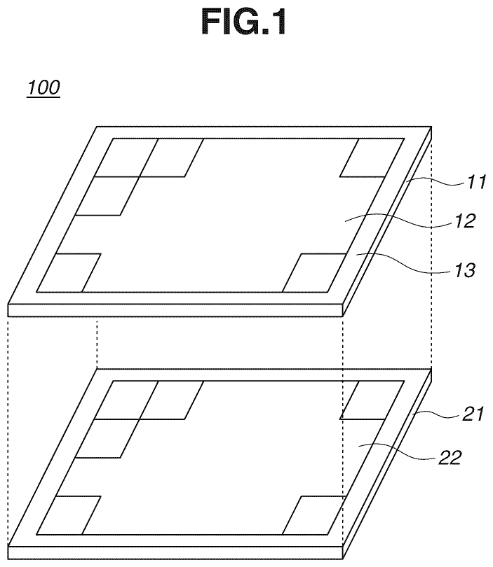

FIG. 1 is a diagram illustrating an overall configuration of a photoelectric conversion apparatus 100. A first substrate 11 is also referred to as a sensor chip and includes a pixel area 12 where pixels including photoelectric conversion units are two-dimensionally arranged. There is a peripheral area 13 between the pixel area 12 and the chip ends of the photoelectric conversion apparatus 100. A second substrate 21 is also referred to as a pixel circuit chip and includes a signal processing circuit area 22 for processing signals from the photoelectric conversion units. The first substrate 11 and the second substrate 21 are stacked to constitute the photoelectric conversion apparatus 100. Although not illustrated in the drawings, a third substrate can be further stacked on the stack of the first and second substrates 11 and 21. In such a case, a signal processing circuit for processing signals output from the second substrate 21 can be disposed on the third substrate. For example, a processing circuit that performs various types of processing by executing programs stored in a memory, using a trained model generated by machine learning may be provided as the signal processing circuit. The trained model is generated by machine learning using a deep neural network (DNN). This signal processing circuit performs calculation processing based on the trained model, using signals output from the pixel area 12. Calculation results include image data obtained by performing the calculation processing using the trained model, and various types of information (metadata) obtained from the image data.

### (Configuration Diagram of First Substrate)

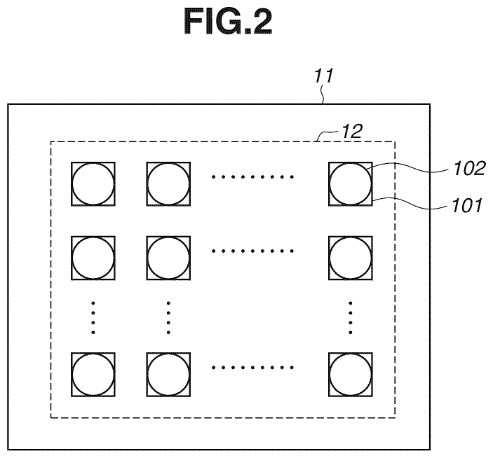

FIG. 2 is a configuration diagram of the first substrate 11. The first substrate 11 includes the pixel area 12 where pixels 101 including photoelectric conversion units 102 are two-dimensionally arranged. Each photoelectric conversion units 102 includes an avalanche photodiode (APD). The pixels 101 may be one-dimensionally arranged in the pixel area 12. Details of the photoelectric conversion units 102 will be described below.

The pixels 101 are typically ones for forming an image. If time-of-flight (ToF) ranging is intended, however, an image does not necessarily need to be formed. In other words, the pixels 101 may be elements for measuring the time of arrival and the amount of light.

### (Configuration Diagram of Second Substrate)

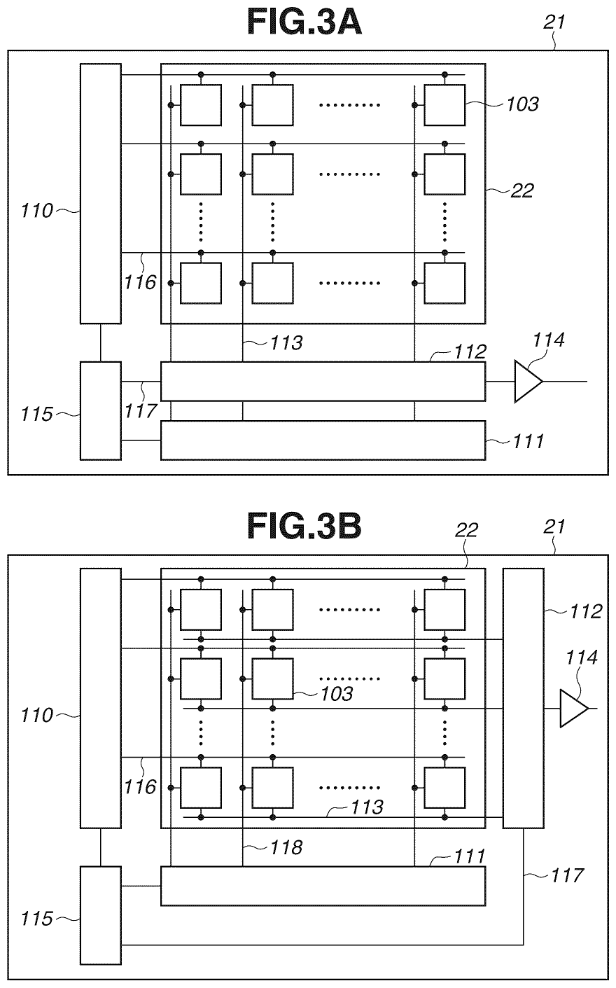

FIG. 3A is a configuration diagram of the second substrate 21. The second substrate 21 includes a plurality of signal processing units 103 for processing signals photoelectrically converted by the photoelectric conversion units 102. The plurality of signal processing units 103 is disposed in the signal processing circuit area 22, which is two-dimensionally laid out. The signal processing units 103 are pixel circuits disposed to correspond to the respective pixels 101. The signal processing units 103 include counters and memories. The memories hold digital values. Signals output from the signal processing units 103 are transmitted to signal lines 113 using a vertical scanning circuit 110 and a horizontal scanning circuit 111.

The vertical scanning circuit 110 receives control pulses supplied from a control pulse generation unit 115 and supplies the control pulses to the pixels 101. A logic circuit such as a shift register and an address decoder is used for the vertical scanning circuit 110.

The horizontal scanning circuit 111 inputs control pulses for sequentially selecting columns into the signal processing units 103 to read signals from the memories of the respective pixels 101 holding the digital signals.

The signals from the signal processing units 103 of the pixels 101 selected by the vertical scanning circuit 110 in the selected columns are output to the respective signal lines 113.

The signals transmitted to the signal lines 113 are output to outside via a reading circuit 112 and an output circuit 114. The signal lines 113 are laid to extend vertically. The vertical scanning circuit 110, the horizontal scanning circuit 111, and the reading circuit 112 are controlled by pulses from the control pulse generation unit 115.

FIG. 3B illustrates another configuration of the second substrate 21. In FIG. 3A, the signal lines 113 are laid to extend vertically (in a column direction). FIG. 3B differs in that the signal lines 113 are laid to extend laterally (horizontally). In FIG. 3A, the reading circuit 112 is located below the signal processing circuit area 22. By contrast, in FIG. 3B, the reading circuit 112 is located on the right of the signal processing circuit area 22.

In FIGS. 2, 3A, and 3B, a signal processing unit 103 is provided for each pixel 101. However, a signal processing unit 103 may be shared by a plurality of pixels 101, for example, and the signal processing may be sequentially performed. This can save the space of the signal processing circuit area 22.

### (Functional Block Diagram of Photoelectric Conversion Apparatus)

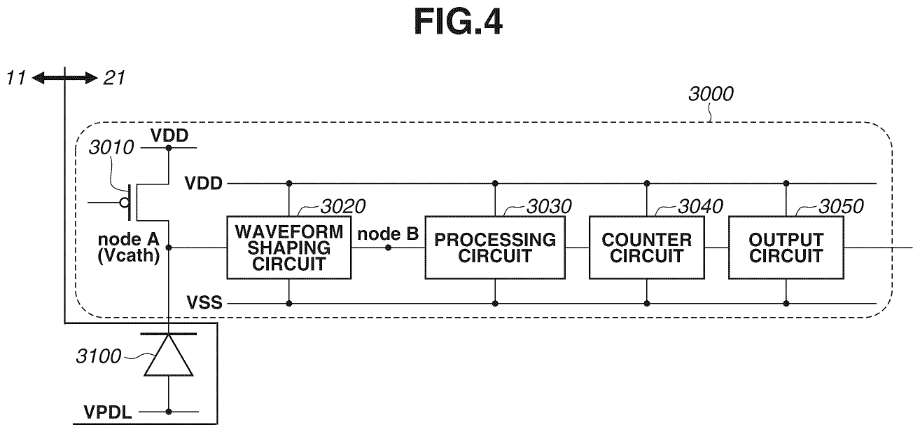

FIG. 4 is a diagram for describing the block diagrams of FIGS. 2, 3A, and 3B in more detail.

FIG. 4 illustrates that an APD 3100 is disposed on the first substrate 11 and the other members are disposed on the second substrate 21.

When light is incident on the APD 3100, a charge pair is generated by photoelectric conversion. A voltage VPDL (first voltage) is supplied to the anode of the APD 3100. A voltage VDD (second voltage) higher than the voltage VPDL supplied to the anode is supplied to the cathode of the APD 3100.

A reverse bias voltage for enabling an avalanche multiplication operation of the APD 3100 is supplied across the anode and the cathode. With such a voltage supplied, the charges resulting from the incident light cause avalanche multiplication and an avalanche current occurs.

A mode where the APD 3100 supplied with a reverse bias voltage operates with a potential difference between the anode and the cathode greater than the breakdown voltage is referred to as a Geiger mode. A mode where the APD 3100 operates with the potential difference between the anode and the cathode near the breakdown voltage or less than or equal to the breakdown voltage is referred to as a linear mode. Among these modes, APDs operating in the Geiger mode are referred to as SPADs. For example, the voltage VPDL (first voltage) is −30 V (volts), and the voltage VDD (second voltage) is 1 V. Here, a potential difference between a voltage VSS (third voltage), or 0 V, and the voltage VPDL (first voltage) is higher than a potential difference between the voltage VSS (third voltage) and the voltage VDD (second voltage). The voltage VPDL (first voltage) may therefore be referred to as high voltage.

A quenching element 3010 is connected to a power supply for supplying the voltage VDD and the APD 3100. The quenching element 3010 has a function of converting a change in the avalanche current occurring in the APD 3100 into a voltage signal. In multiplying a signal by avalanche multiplication, the quenching element 3010 functions as a load circuit (quenching element) to reduce the voltage supplied to the APD 3100 and suppress the avalanche multiplication (quenching operation).

A pixel circuit 3000 includes a waveform shaping circuit 3020, a processing circuit 3030, a counter circuit 3040, and an output circuit 3050 aside from the quenching element 3010.

The waveform shaping circuit 3020 shapes the waveform of the change in the potential at the cathode of the APD 3100 obtained during photon detection and outputs a pulse signal. For example, an inverter circuit is used for the waveform shaping circuit 3020. The waveform shaping circuit 3020 may be a single inverter, a circuit including a plurality of inverters connected in series, or other circuits having a waveform shaping effect.

The processing circuit 3030 is a circuit that performs predetermined signal processing. For example, the processing circuit 3030 is a circuit for selecting whether to input the signal output from the waveform shaping circuit 3020 to the counter circuit 3040. More specifically, the processing circuit 3030 is configured to input the pulse signal output from the waveform shaping circuit 3020 to the counter circuit 3040 in an exposure period. The processing circuit 3030 is also configured to not input the pulse signal output from the waveform shaping circuit 3020, if any, to the counter circuit 3040 in a non-exposure period. As will be described below, the exposure period and the non-exposure period can be set and switched by controlling the quenching element 3010. The provision of the processing circuit 3020 enables control of the exposure period and the non-exposure period without controlling the quenching element 3010.

The counter circuit 3040 counts the pulse signal output from the waveform shaping circuit 3020 and holds the count. When a control pulse pRES is supplied via a driving line (not illustrated), the signal (count) held in the counter circuit 3040 is reset. Providing the counter circuit 3040 for each pixel 101 increases the circuit scale. A third substrate may therefore be provided and the counter circuits 3040 may be disposed not only on the second substrate 21 but partly on the third substrate as well.

In FIG. 4, the quenching element 3010 is constituted by a metal-oxide-semiconductor (MOS) transistor. Clock cycle pulses may also be applied to the gate of the MOS transistor. In such a case, pulses having a predetermined clock period are input to the gate of the quenching element 3010 from a not-illustrated phase-locked loop (PLL) circuit. For example, when a pulse from the PLL circuit is at a high level, the quenching element 3010 turns off since the quenching element 3010 is a P-channel MOS (PMOS) transistor. In such a case, the APD 3100 is not recharged and enters a non-detection mode. On the other hand, when a pulse from the PLL circuit is at a low level, the quenching element 3010 turns on and the APD 3100 is recharged to enter a detection mode (standby mode). Since the clock pulses from the PLL circuit have a predetermined period, the output signal is forcefully reset at every clock cycle. The photon count for a single pulse is thus one, and as many signals as the number of incident photons can thus be generated even under high illuminance. The PLL circuit is disposed on either the first substrate 11 or the second substrate 21.

The output circuit 3050 outputs the digital signal output from the counter circuit 3040 to outside. For example, an open-drain buffer is used as the output circuit 3050. If the photoelectric conversion apparatus 100 performs additional calculation as described above, the output circuit 3050 outputs the digital signal not to outside but to a signal processing circuit included in the photoelectric conversion apparatus 100.

The voltage VDD (second voltage) and the voltage VSS (third voltage) are supplied to the waveform shaping circuit 3020, the processing circuit 3030, the counter circuit 3040, and the output circuit 3050 as driving voltages.

In the foregoing description, the pixel circuit 3000 is described to include the counter circuit 3040 as an example. However, a time-to-digital converter (TDC) circuit serving as a time measuring circuit may also be included instead of the counter circuit 3040. The photoelectric conversion apparatus 100 is thereby configured to obtain pulse detection timing.

Here, the generation timing of the pulse signal output from the waveform shaping circuit 3020 is converted into a digital signal by the TDC circuit. To measure the generation timing of the pulse signal, a control pulse pREF (reference signal) is supplied to the TDC circuit from the vertical scanning circuit 110 illustrated in FIG. 3A or 3B via a driving line. For the digital signal, the TDC circuit obtains a signal indicating the input timing of the signal output from the APD 3100 via the waveform shaping circuit 3020 as relative time with reference to the control pulse pREF.

The TDC circuit includes, for example, a reset-set (RS) flip-flop, a coarse counter, and a fine counter. The control pulse pREF drives a light emitting unit and sets the RS flip-flop. The RS flip-flop is reset by a signal pulse input from the APD 3100. A signal having a pulse width corresponding to the time of flight of the light is thereby generated. The generated signal is counted by the coarse counter and the fine counter with respective predetermined time resolutions. A digital code is thereby output.

The PLL circuit for generating the control pulse pREF for the TDC circuit is disposed on either the first substrate 11 or the second substrate 21, or on both the first and second substrates 11 and 12. However, a delay in the control pulse pREF input to the TDC circuit affects the accuracy of information output from the TDC circuit. The PLL circuit is thus desirably disposed on the same substrate as is the TDC circuit. For example, in the present exemplary embodiment, the TDC circuit and the PLL circuit are disposed on the second substrate 21.

Instead of replacing the counter circuit 3040 with the TDC circuit, the counter circuit 3040 and the TDC circuit can also be both provided.

### (Relationship Between Operation of APD and Output Signal)

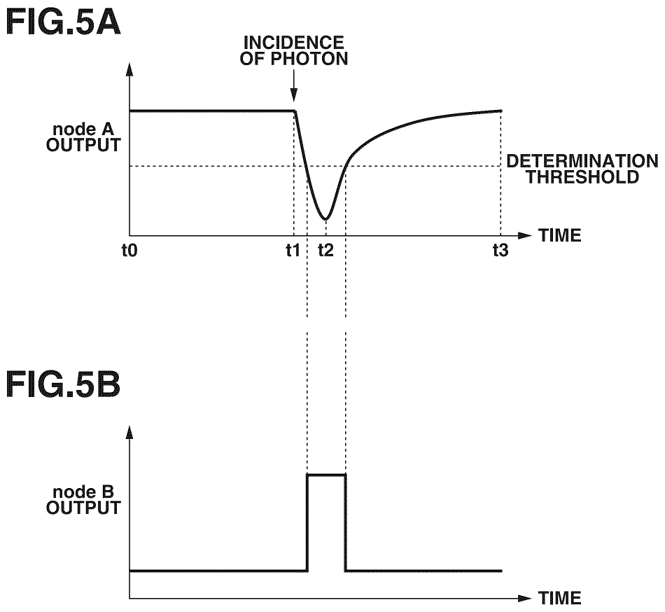

FIGS. 5A and 5B are diagrams schematically illustrating a relationship between the operation of the APD 3100 and the output signal. Returning to FIG. 4, the input Vcath of the waveform shaping circuit 3020 will be referred to as node A, and the output as node B. FIG. 5A illustrates a waveform change on node A of FIG. 4, and FIG. 5B a waveform change on node B of FIG. 4.

Between time t0 and time t1, a potential difference capable of avalanche multiplication is applied. A photon is incident at time t1. An avalanche multiplication current flows through the quenching element 3010, and the voltage of node A drops. As the amount of voltage drop increases, the potential difference applied to the APD 3100 decreases. The avalanche multiplication of the APD 3100 stops, and the voltage level of node A stops dropping beyond a certain value. A current compensating for the voltage drop flows from the node of the voltage VPDL to node A, and at time t3, node A settles at the original potential level. Here, the portion of the output waveform on node A exceeding a threshold is shaped by the waveform shaping circuit 3020 and output as a signal from node B.

### (Sectional View of Photoelectric Conversion Apparatus)

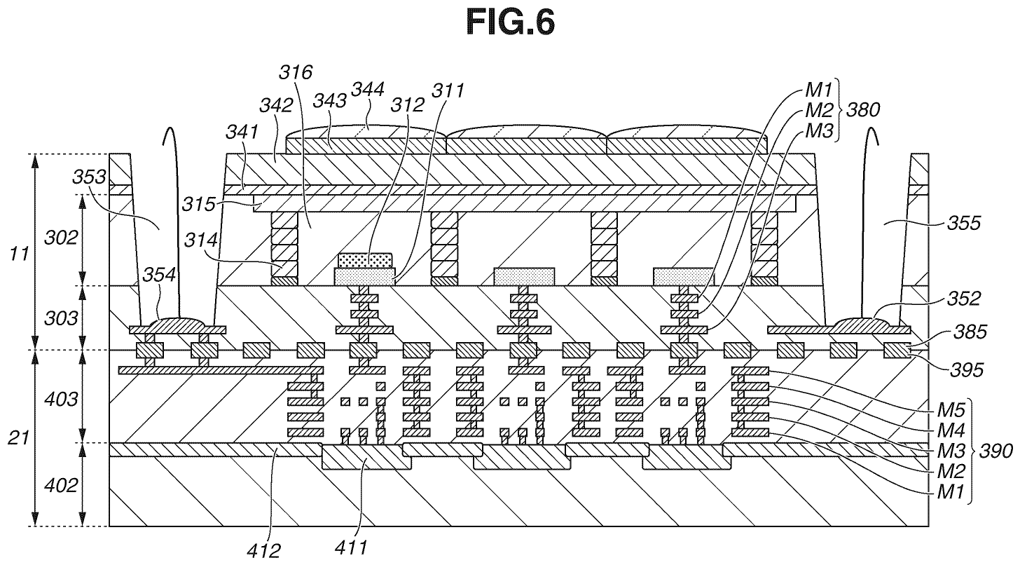

FIG. 6 is a sectional view of the photoelectric conversion apparatus 100, and light is incident from the top of FIG. 6. The first substrate 11 and the second substrate 21 are stacked in order from the light incident surface side.

The first substrate 11 includes a semiconductor layer 302 (first semiconductor layer) of the first substrate 11 and a wiring structure 303 (first wiring structure) of the first substrate 11. The second substrate 21 includes a semiconductor layer 402 (second semiconductor layer) of the second substrate 21 and a wiring structure 403 (second wiring structure) of the second substrate 21.

The first substrate 11 and the second substrate 21 are bonded such that the first wiring structure 303 and the second wiring structure 403 are opposed to and in contact with each other.

The first semiconductor layer 302 includes first semiconductor regions 311 of a first conductivity type and second semiconductor regions 316 of a second conductivity type, which form positive-negative (PN) junctions to constitute APDs 3100 illustrated in FIG. 4.

On the light incident surface side of the second semiconductor regions 316, third semiconductor regions 312 of the second conductivity type are located. The third semiconductor regions 312 have an impurity concentration lower than that of the second semiconductor regions 316. As employed herein, an “impurity concentration” refers to a net impurity concentration compensated by impurities of the opposite conductivity type. In other words, the “impurity concentration” refers to a net concentration. For example, a region where the P-type doping impurity concentration is higher than the N-type doping impurity concentration is a P-type semiconductor region. By contrast, a region where the N-type doping impurity concentration is higher than the P-type doping impurity concentration is an N-type semiconductor region.

The pixels are isolated by fourth semiconductor regions 314 of the second conductivity type. On the light incident surface side of the fourth semiconductor regions 314, a fifth semiconductor region 315 of the second conductivity type is located. The fifth semiconductor region 315 is provided for the pixels in common.

The voltage VPDL (first voltage) illustrated in FIG. 4 is supplied to the fourth semiconductor regions 314. The voltage VDD (second voltage) illustrated in FIG. 4 is supplied to the first semiconductor regions 311. The voltage supplied to the fourth semiconductor regions 314 and the voltage supplied to the first semiconductor regions 311 provide a reverse bias voltage between the second semiconductor regions 312 and the first semiconductor regions 311. The reverse bias voltage for enabling the avalanche multiplication operation of the APDs 3100 is thereby supplied.

On the light incident surface side of the fifth semiconductor region 315, a pinning layer 341 is located. The pinning layer 341 is provided for dark current suppression. The pinning layer 341 is formed of hafnium oxide (HfO₂), for example. Zirconium dioxide (ZrO₂) or tantalum oxide (Ta₂O₅) may be used to form the pinning layer 341.

On the pinning layer 341, microlenses 344 are disposed via an insulating layer 342 and color filters 343. The insulating layer 342 and the color filters 343 are optional components. Between the microlenses 344 and the pinning layer 341, a grid-like light shielding film for optically isolating the pixels may be interposed. The light shielding film may be made of any material that can shield light. Examples may include tungsten (W), aluminum (Al), and copper (Cu).

The second semiconductor layer 402 includes active regions 411 made of semiconductor regions, and isolation regions 412. The isolation regions 412 are field regions made of an insulator.

The first wiring structure 303 includes a plurality of wiring layers 380 constituted by stacking a plurality of insulator layers and a plurality of metal layers. As employed herein, a wiring layer refers to a layer including metal traces disposed on or under an interlayer film made of an insulator layer, and insulator members located between the metal traces. As employed herein, metal traces (via wiring and contact wiring) formed in an interlayer film to connect the wiring of a first wiring layer and the wiring of a second wiring layer are not referred to as a wiring layer. The plurality of wiring layers 380 includes, from the side of the first semiconductor layer 302, a first wiring layer (M1), a second wiring layer (M2), and a third wiring layer (M3). The topmost layer of the first wiring structure 303 includes first bonding portions 385 exposed from the first wiring structure 303. The first wiring structure 303 also has a pad opening 353 (first pad opening) and a pad opening 355 (second pad opening). On the bottoms of the pad openings 353 and 355, pad electrodes 354 and 352 are disposed, respectively. The pad electrode 352 is an electrode for supplying a voltage to the circuits on the first substrate 11. For example, the voltage VPDL (first voltage) is supplied from the pad electrode 352 to the fourth semiconductor regions 314 through via wiring (not illustrated) and contact wiring (not illustrated). Since the voltage VPDL (first voltage) is a high voltage, the semiconductor elements disposed on the second semiconductor layer 402 can be affected if the high voltage wiring is included in the second wiring structure 403. The wiring electrically connected to the pad electrode 352 is therefore configured to supply the voltage VPDL to the fourth semiconductor regions 314 without the intermediary of the wiring of the second wiring structure 403. In other words, the high voltage is supplied from the pad electrode 352 disposed on the first wiring structure 303 without going through the bonding surface between the first wiring structure 303 and the second wiring structure 403.

The second wiring structure 403 includes a plurality of wiring layers 390 constituted by stacking a plurality of insulator layers and a plurality of metal layers. The plurality of wiring layers 390 includes, from the side of the second semiconductor layer 402, a first wiring layer (M1) to a fifth wiring layer (M5). The topmost layer of the second wiring structure 403 includes second bonding portions 395 exposed from the second wiring structure 403. The bonding portions 385 of the first substrate 11 are in contact with the bonding portions 395 of the second wiring structure 403 for electrical connection. Such bonding of the first bonding portions 385 exposed in the bonding surface of the first substrate 11 and the second bonding portions 395 exposed in the bonding surface of the second substrate 21 may be referred to as a metal bonding (MB) structure or metal bonding portions. This bonding is often made between copper (Cu) portions and can thus be called Cu—Cu bonding.

The pad electrodes 354 disposed on the first wiring structure 303 are electrically connected to any of the wiring included in the plurality of wiring layers 390 via first and second bonding portions 385 and 395. For example, the voltage VSS (third voltage) is supplied to the circuits included in the pixel circuits 3000 from a pad electrode 354. The voltage VDD (second voltage) is supplied to the circuits included in the pixel circuits 3000 from another pad electrode 354. A voltage is supplied to the wiring of the plurality of wiring layers 390 from another pad electrode 354 via first and second bonding portions 385 and 395. A voltage is supplied to the wiring of the plurality of wiring layers 380 from another pad electrode 354 via second and first bonding portions 395 and 385. For example, the voltage VDD (second voltage) to be electrically connected to the quenching elements 3010 is supplied from the pad electrode 354 through such a path. Specifically, the voltage VDD (second voltage) is supplied to first and second bonding portions 385 and 395 and the wiring of the plurality of wiring layers 390 from the pad electrode 354. The voltage VDD (second voltage) is then supplied from the wiring of the plurality of wiring layers 390 to the first semiconductor regions 311 via the quenching elements 3010 included in the second substrate 21, the wiring of the plurality of wiring layers 390, and second and first bonding portions 395 and 385.

While FIG. 6 illustrates only one pad electrode 354, a plurality of pad electrodes 354 is provided to supply voltages of different values.

### (Wiring Configuration Example 1-1 of Plurality of Wiring Layers)

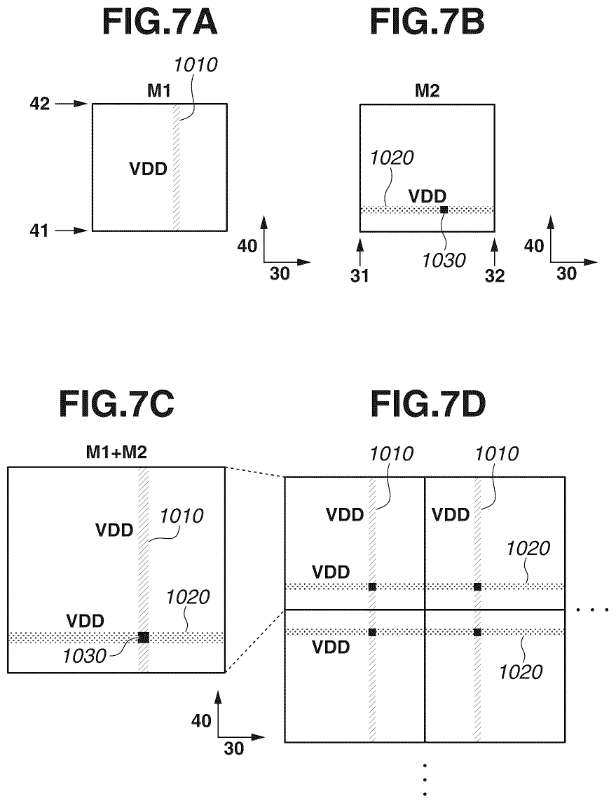

FIGS. 7A to 7D are diagrams illustrating a wiring layout of the voltage VDD (second voltage) illustrated in FIG. 4. As described with reference to FIG. 4, an APD sensor including SPADs includes a large number of circuits constituting the pixel circuits 3000 provided pixel by pixel. The APD sensor therefore includes a large number of power supply lines to the circuits and a large number of input and output lines to/from the circuits and has a high wiring density between the circuits. The higher the wiring density, the more likely the wiring of the voltage VDD (second voltage) and the voltage VSS (third voltage) serving as power supplies for the circuits is to be divided. This can interfere with stable current supply. As employed herein, being divided refers to the absence of power supply wiring two-dimensionally laid out on a wiring layer. That power supply wiring is two-dimensionally laid out means that in a region where a pixel circuit of a single pixel is disposed, the power supply wiring is laid to reach both ends in a first direction and both ends in a second direction. If pixel circuits of a plurality of pixels are laid out without such wiring, the wiring of the pixel circuits of adjoining pixels is unable to be electrically connected.

In particular, SPADs count a large number of photons under high illuminance, and a large amount of current flows through the power supply wiring of the circuits constituting the pixel circuits. The power supply wiring to the pixel circuits is therefore desirably laid out without being divided. Moreover, since the number of incident photons and the timing of incidence vary from one pixel circuit to another, the magnitude and timing of the current to flow also varies from one pixel circuit to another. The power supply wiring to the pixel circuits is therefore also desirably laid out without being divided.

FIGS. 7A and 7B illustrate a region where a pixel circuit 3000 of a single pixel is disposed, extracted from the pixel circuits 3000 included in the second substrate 21. Such a region is also referred to as a region where a pixel circuit for a single unit is disposed.

FIG. 7A is a plan view illustrating a layout example of a trace 1010 of the voltage VDD (second voltage), disposed on the first wiring layer (M1). FIG. 7B is a plan view illustrating a layout example of a trace 1020 of the voltage VDD (second voltage), disposed on the second wiring layer (M2).

In FIG. 7A, the trace 1010 is disposed to extend in a second direction 40. Specifically, the trace 1010 is disposed to extend in the second direction 40 between both ends, or from an end 41 to an end 42, of the region where the pixel circuit of a single pixel is disposed. The trace 1010 is not disposed to extend in a first direction 30 that is a direction intersecting (here, orthogonal to) the second direction 40. The first wiring layer (M1) includes wiring for connecting the circuits constituting the pixel circuit and gate wiring at high density. The trace 1010 is thus obstructed by other wiring and unable to be extended in the first direction 30 on the first wiring layer (M1).

As illustrated in FIG. 7B, the trace 1020 on the second wiring layer (M2) is disposed to extend in the first direction 30 between both ends, or from an end 31 to an end 32, of the region in the first direction 30, and the trace 1020 and the trace 1010 are electrically connected by a via 1030. The wiring of the voltage VDD (second voltage) is thereby extended in both the first and second directions 30 and 40 by the combination of the two wiring layers.

As described above, in a region where the pixel circuit of a single pixel is disposed, both ends in the first direction 30 are connected by the trace 1020 of the second wiring layer and both ends in the second direction 40 are connected by the trace 1010 of the first wiring layer. In other words, the region where the pixel circuit of a single pixel is disposed is configured such that both ends in the first direction 30 and both ends in the second direction 40 are connected in a plan view by the combination of the traces of the two wiring layers.

The foregoing configuration enables a two-dimensional layout of power supply wiring even if the wiring density is high and the wiring for a power supply voltage is unable to be two-dimensionally laid out using only one wiring layer. If a first pixel of high current consumption and a second pixel of low current consumption adjoin each other and the current consumption from the power supply wiring of the pixel circuit of the first pixel is high, a current can thus be supplied to the pixel circuit of the first pixel from the power supply wiring of the pixel circuit of the second pixel. This enables stable current supply to the pixel circuits.

FIG. 7C illustrates an example where the wiring of a pixel is extended both in the first direction 30 and the second direction 40 using two wiring layers. FIG. 7D illustrates four pixels. The wiring layouts of the respective pixels are symmetrical about the border lines between the pixels. Such an arrangement may be referred to as a mirror symmetrical arrangement. Although not illustrated in the diagram, other pixels adjoining the illustrated four pixels are also in such a line-symmetrical arrangement.

As illustrated in FIG. 7D, the regions where the pixel circuit of a single pixel is disposed are also regions where a predetermined wiring pattern is repeated. While FIG. 7D illustrates an example of the mirror symmetrical arrangement, the regions where the pixel circuit of a single pixel is disposed are repeated even with such a mirror symmetrical arrangement. While FIG. 7D illustrates an example of the mirror symmetrical arrangement, a translationally symmetrical arrangement may be employed. Even in such a case, the regions where the pixel circuit of a single pixel is disposed are repeated.

In the foregoing description, the lateral direction of the drawings is referred to as the first direction 30 and the vertical direction the second direction 40. However, the vertical direction may be referred to as the first direction 30 and the lateral direction the second direction 40.

### (Wiring Configuration Example 1-2 of Plurality of Wiring Layers)

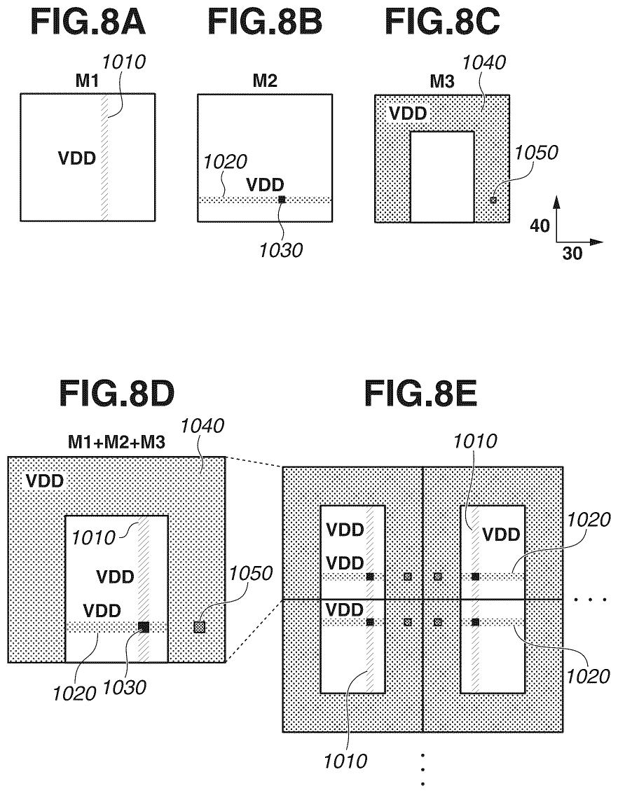

FIGS. 8A to 8E are diagrams illustrating wiring on the first wiring layer (M1), the second wiring layer (M2), and a third wiring layer (M3) that is an upper wiring layer than the first wiring layer (M1) and the second wiring layer (M2).

FIGS. 8A and 8B are the same as FIGS. 7A and 7B. A description thereof will thus be omitted.

FIG. 8C is a diagram illustrating a trace 1040 for supplying the voltage VDD (second voltage), disposed on the third wiring layer (M3). As illustrated in FIG. 8D, the trace 1040 disposed on the third wiring layer (M3) and the trace 1020 disposed on the second wiring layer (M2) are electrically connected by a via 1050. In the region where the pixel circuit of a single pixel is disposed, the trace 1040 of the third wiring layer (M3) connects both ends in the first direction 30 and both ends in the second direction 40 in a plan view only on the third wiring layer (M3). Meanwhile, the first wiring layer (M1) and the second wiring layer (M2) are configured such that, in the region where the pixel circuit of a single pixel is disposed, both ends in the first direction 30 and both ends in the second direction 40 are connected in a plan view by the combination of the traces of the two wiring layers.

FIG. 8E illustrates four pixels in a mirror symmetrical arrangement.

As a general rule of semiconductor processes, traces on a wiring layer located farther from a semiconductor layer (upper wiring layer) can have a greater wiring width compared to traces on a wiring layer located closer to the semiconductor layer (lower wiring layer). Specifically, the third wiring layer (M3) is the wiring layer where the area occupied by the wiring of the voltage VDD (second voltage) is the largest among the plurality of wiring layers. As illustrated in FIG. 8C, the trace 1040 for supplying the voltage VDD (second voltage) on the third wiring layer (M3) thus has an increased wiring width for reduced resistance.

The trace 1040 for supplying the voltage VDD (second voltage) on the third wiring layer (M3) is extended to connect both ends in the first direction 30 and both ends in the second direction 40. However, the distance between the third wiring layer (M3) and the second semiconductor layer 402 where the pixel circuits are disposed is greater than the distance between the second wiring layer (M2) and the second semiconductor layer 402 and the distance between the first wiring layer (M1) and the second semiconductor layer 402. The third wiring layer (M3) alone can therefore be insufficient to supply current from the pixel circuit of a pixel of low current consumption to the pixel circuit of a pixel of high current consumption. The first wiring layer (M1) and the second wiring layer (M2) are therefore combined to two-dimensionally lay out the power supply wiring even in such a case. This enables stable current supply to the pixel circuits.

In the foregoing example, the first wiring layer (M1) and the second wiring layer (M2) can be referred to as a lower wiring layer group since the first and second wiring layers are a plurality of wiring layers located between the wiring layer where the area occupied by the wiring is the largest and the second semiconductor layer 402. Alternatively, the first and second wiring layers may be referred to simply as a wiring layer group.

### (Wiring Configuration Example 1-3 of Plurality of Wiring Layers)

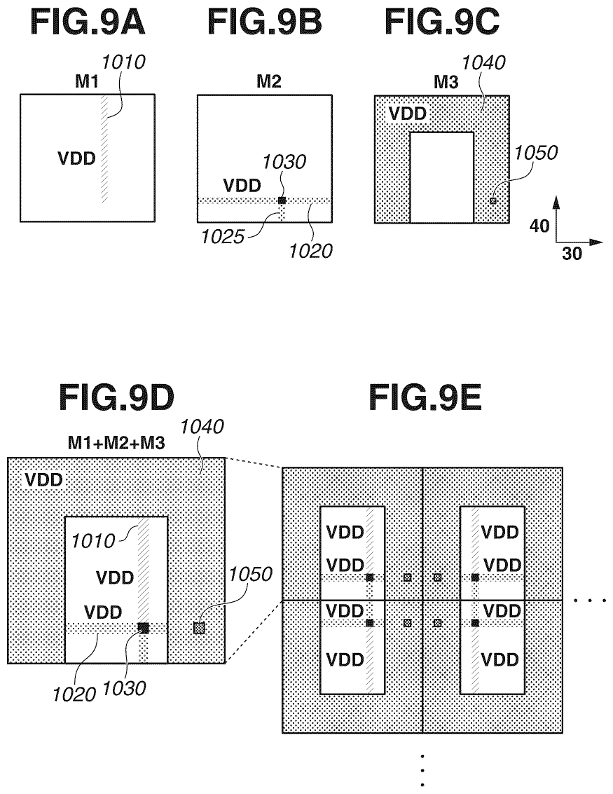

FIGS. 9A to 9E are diagrams illustrating wiring on the first wiring layer (M1) to the third wiring layer (M3). FIG. 9C is the same as FIG. 8C, and a description thereof will thus be omitted.

FIG. 9A is a diagram illustrating a trace 1010 for supplying the voltage VDD (second voltage), disposed on the first wiring layer (M1). In FIG. 8A, the trace 1010 extends in the second direction 40 to reach both ends of the region including the pixel circuit of a single pixel in the second direction 40. By contrast, the trace 1010 of FIG. 9A differs in not reaching both ends of the region in the first direction 30 or both ends in the second direction 40.

FIG. 9B is a diagram illustrating a trace 1020 for supplying the voltage VDD (second voltage), disposed on the second wiring layer (M2). Like FIG. 8B, the trace 1020 of FIG. 9B also extends in the first direction 30 to reach both ends of the region including the pixel circuit of a single pixel in the first direction 30. In addition, in FIG. 9B, a trace 1025 extending in the second direction 40 in the region is also disposed.

In other words, in the example illustrated in FIGS. 9A to 9E, neither of the first wiring layer (M1) and the second wiring layer (M2) in the region including the pixel circuit of a single pixel includes a trace two-dimensionally connected to the ends of the region. However, wiring that connects both ends of the region in the first direction 30 and both ends in the second direction 40 is configured by combining the first wiring layer (M1) and the second wiring layer (M2).

In the examples illustrated in FIGS. 7A to 7D and 8A to 8E, the first wiring layer (M1) includes a trace connected to both ends of the region including the pixel circuit of a single pixel. The second wiring layer (M2) also includes a trace connected to both ends of the region including the pixel circuit of a single pixel. By contrast, as illustrated in FIG. 9A, the trace disposed on the first wiring layer (M1) may also be connected to one end of the region including the pixel circuit of a single pixel and not to the other.

### (Other Configuration Examples)

The foregoing examples have dealt with the wiring of the voltage VDD (second voltage). However, not only the wiring of the voltage VDD (second voltage) but the wiring of the voltage VSS (third voltage) may also be laid out as illustrated in FIGS. 7A to 9E.

The foregoing examples have dealt with the wiring layout of the voltage VDD (second voltage) to the first wiring layer (M1) that is the wiring layer closest to the semiconductor layer included in the second substrate 21 and the second wiring layer (M2) that is the second closest wiring layer. However, since the power supply wiring can be two-dimensionally laid out using a plurality of wiring layers, the third wiring layer (M3) and a fourth wiring layer (M4) closer to the first substrate 11 than the second wiring layer (M2) may be used to two-dimensionally lay out the power supply wiring. Alternatively, all the first to third wiring layers (M1 to M3) may be used to two-dimensionally lay out the power supply wiring.

In the foregoing examples, the combined wiring of the wiring layer group is two-dimensional wiring including two straight traces. However, the combined wiring may have a more complex shape as long as the wiring is laid out to reach both ends in the first direction 30 and both ends in the second direction 40, of the region including the pixel circuit of a single pixel.

A second exemplary embodiment describes an example where the wiring of a voltage VDD (second voltage) and the wiring of a voltage VSS (third voltage) are two-dimensionally laid out by combining a plurality of wiring layers. In the present exemplary embodiment, an example of two-dimensionally laying out the power supply wiring by combining three wiring layers (wiring layer group) will be described.

### (Wiring Configuration Example 2-1 of Plurality of Wiring Layers)

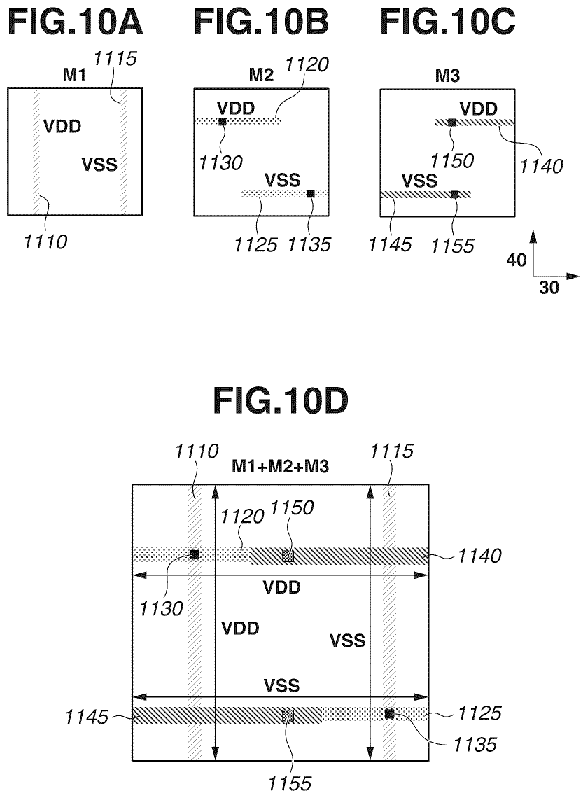

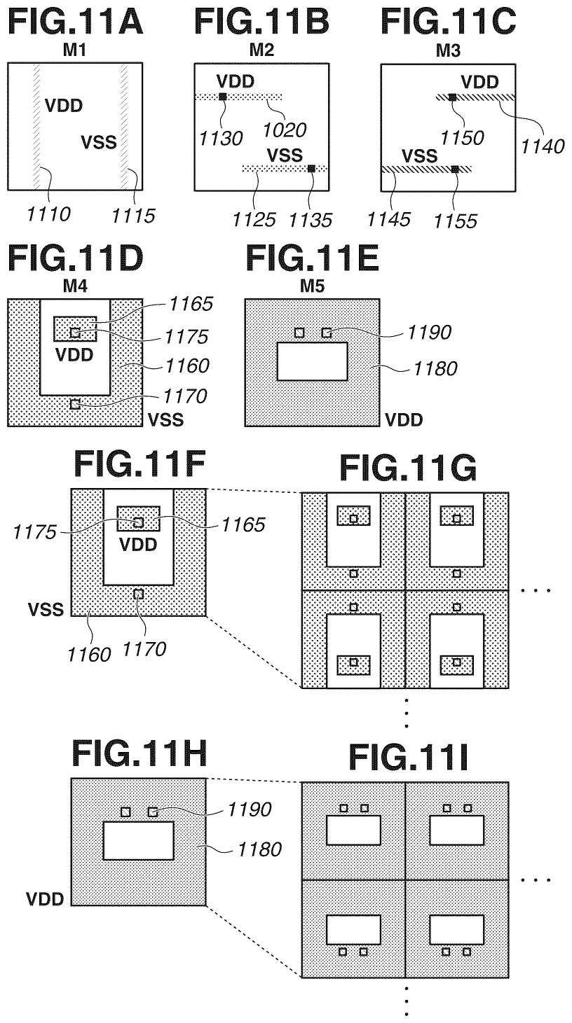

FIGS. 10A to 10C are diagrams illustrating the layout of the wiring of the voltage VDD (second voltage) and the voltage VSS (third voltage) illustrated in FIG. 4. As described with reference to FIG. 4, an APD sensor including SPADs includes a large number of circuits constituting pixel circuits 3000 provided pixel by pixel. The APD sensor thus includes a large number of power supply lines to the circuits and a large number of input and output lines to/from the circuits and has a high wiring density between the circuits. The higher the wiring density, the more likely the wiring of the voltage VDD (second voltage) and the voltage VSS (third voltage) serving as power supplies for the circuits is to be divided. This can interfere with stable current supply.

FIGS. 10A to 10C illustrate a region where a pixel circuit 3000 of a single pixel is disposed, extracted from the pixel circuits 3000 included in a second substrate 21. FIG. 10D illustrates the regions of FIGS. 10A to 10C superposed.

FIG. 10A illustrates a layout example of a trace 1110 of the voltage VDD (second voltage) and a trace 1115 of the voltage VSS (third voltage), disposed on a first wiring layer (M1). In the region including the pixel circuit of a single pixel, the traces 1110 and 1115 are disposed to extend in a second direction 40 to reach both ends of the region in the second direction 40. The reason is that the wiring is unable to be two-dimensionally extended because wiring for connecting the circuits constituting the pixel circuit 3000 and gate wiring are disposed at high density.

FIG. 10B illustrates the layout of a trace 1120 of the voltage VDD (second voltage) and a trace 1125 of the voltage VSS (third voltage), disposed on a second wiring layer (M2). The traces 1120 and 1125 are each extended in a first direction 30 from one end of the region and do not reach the other end of the region. The reason is that the traces are unable to be extended to reach both ends of the region even in a one-dimensional direction because wiring for connecting the circuits constituting the pixel circuit 3000 and gate wiring are disposed at high density.

FIG. 10C illustrates the layout of a trace 1140 of the voltage VDD (second voltage) and a trace 1145 of the voltage VSS (third voltage), disposed on a third wiring layer (M3). The traces 1140 and 1145 are each extended in the first direction 30 from the other end of the region and do not reach the one end of the region. The reason is that the traces are unable to be extended to reach both ends of the region even in a one-dimensional direction because wiring for connecting the circuits constituting the pixel circuit 3000 and gate wiring are disposed at high density.

As described above, none of the first wiring layer (M1), the second wiring layer (M2), and the third wiring layer (M3) can be used to two-dimensionally lay out the power supply wiring by itself.

The second wiring layer (M2) and the third wiring layer (M3) are then used to configure wiring that extends in the first direction 30 and reaches both ends of the region. Specifically, the trace 1120 of the voltage VDD (second voltage) on the second wiring layer (M2) and the trace 1140 on the third wiring layer (M3) are electrically connected by a via 1150. Similarly, the trace 1125 of the voltage VSS (third voltage) on the second wiring layer (M2) and the trace 1145 on the third wiring layer (M3) are electrically connected by a via 1155.

Moreover, the first wiring layer (M1) to the third wiring layer (M3) are used to configure wiring that extends in the first direction 30 and the second direction 40 and reaches the ends of the region. Specifically, the trace 1110 of the voltage VDD (second voltage) on the first wiring layer (M1) and the trace 1120 of the voltage VDD on the second wiring layer (M2) are electrically connected by a via 1130. Similarly, the trace 1115 of the voltage VSS (third voltage) on the first wiring layer (M1) and the trace 1125 of the voltage VSS (third voltage) on the second wiring layer (M2) are electrically connected by a via 1135.

With such a configuration, the power supply wiring can be two-dimensionally laid out by combining the first wiring layer (M1) to the third wiring layer (M3). If a first pixel of high current consumption and a second pixel of low current consumption adjoin each other and the current consumption from the power supply wiring of the pixel circuit of the first pixel is high, a current can thus be supplied from the power supply wiring of the pixel circuit of the second pixel to the pixel circuit of the first pixel. This enables stable current supply to the pixel circuits.

### (Wiring Configuration Example 2-2 of Plurality of Wiring Layers)

FIGS. 11A to 11I are diagrams illustrating wiring on the first wiring layer (M1), the second wiring layer (M2), the third wiring layer (M3), as well as a fourth wiring layer (M4) and a fifth wiring layer (M5) that are upper wiring layers than the third wiring layer (M3).

FIGS. 11A to 11C are the same as FIGS. 10A to 10C. A description thereof will thus be omitted.

FIG. 11D is a diagram illustrating the layout of a trace 1160 for supplying the voltage VSS (third voltage) and a trace 1165 for supplying the voltage VDD (second voltage), disposed on the fourth wiring layer (M4). The trace 1160 disposed on the fourth wiring layer (M4) and the trace 1145 disposed on the third wiring layer (M3) are electrically connected by a via 1170.

FIG. 11F is the same as FIG. 11D. FIG. 11G illustrates four pixels in a mirror symmetrical arrangement. The trace 1160 disposed on the fourth wiring layer (M4) connects both ends in the first direction 30 and both ends in the second direction 40 in a plan view on the fourth wiring layer (M4) alone. The fourth wiring layer (M4) is a wiring layer where the area occupied by the wiring of the voltage VSS (third voltage) is the largest among the plurality of wiring layers. The trace 1160 for supplying the voltage VSS (third voltage), disposed on the fourth wiring layer (M4) thus has an increased wiring width for reduced resistance. The distance between the fourth wiring layer (M4) and the second semiconductor layer 402 where the pixel circuits are disposed is greater than that between any of the first to third wiring layers (M1 to M3) and the second semiconductor layer 402. The fourth wiring layer (M4) alone can therefore be insufficient to supply current from the pixel circuits of pixels of low current consumption to the pixel circuits of pixels of high consumption. In the present exemplary embodiment, the first to third wiring layers (M1 to M3) are therefore combined to two-dimensionally lay out the power supply wiring. This enables stable current supply to the pixel circuits.

FIG. 11E is a diagram illustrating the layout of a trace 1180 for supplying the voltage VDD (second voltage), disposed on the fifth wiring layer (M5). The trace 1180 disposed on the fifth wiring layer (M5) and the trace 1165 disposed on the fourth wiring layer (M4) are electrically connected by vias 1190. The trace 1165 disposed on the fourth wiring layer (M4) and the trace 1140 disposed on the third wiring layer (M3) are electrically connected by a via 1175.

FIG. 11H is the same as FIG. 11E. FIG. 11I illustrates four pixels in a mirror symmetrical arrangement. The trace 1180 disposed on the fifth wiring layer (M5) connects both ends in the first direction 30 and both ends in the second direction 40 in a plan view on the fifth wiring layer (M5) alone. The fifth wiring layer (M5) is a wiring layer where the area occupied by the wiring of the voltage VDD (second voltage) is the largest among the plurality of wiring layers. The trace 1180 for supplying the voltage VDD (second voltage), disposed on the fifth wiring layer (M5) thus has an increased wiring width for reduced resistance. The distance between the fifth wiring layer (M5) and the second semiconductor layer 402 where the pixel circuits are disposed is greater than that between any of the first to fourth wiring layers (M1 to M4) and the second semiconductor layer 402. The fifth wiring layer (M5) alone can therefore be insufficient to supply current from the pixel circuits of pixels of low current consumption to the pixel circuits of pixels of high consumption. In the present exemplary embodiment, the first wiring layer (M1) to the third wiring layer (M3) are therefore combined to two-dimensionally lay out the power supply wiring. This enables stable current supply to the pixel circuits.

In the foregoing example, the fourth wiring layer (M4) and the fifth wiring layer (M5) are allocated as wiring layers where the areas occupied by the wiring of the respective two types of power supply voltages are the largest. Moreover, the first wiring layer (M1) to the third wiring layer (M3) are combined to two-dimensionally lay out the power supply wiring. However, the third wiring layer (M3) and the fifth wiring layer (M5) may be allocated as the wiring layers where the areas occupied by the wiring of the respective two types of power supply voltages are the largest. In such a case, the first wiring layer (M1), the second wiring layer (M2), and the fourth wiring layer (M4) may be combined to two-dimensionally lay out the power supply wiring.

A third exemplary embodiment deals with a layout example of the pixel circuit 3000 described with reference to FIG. 4.

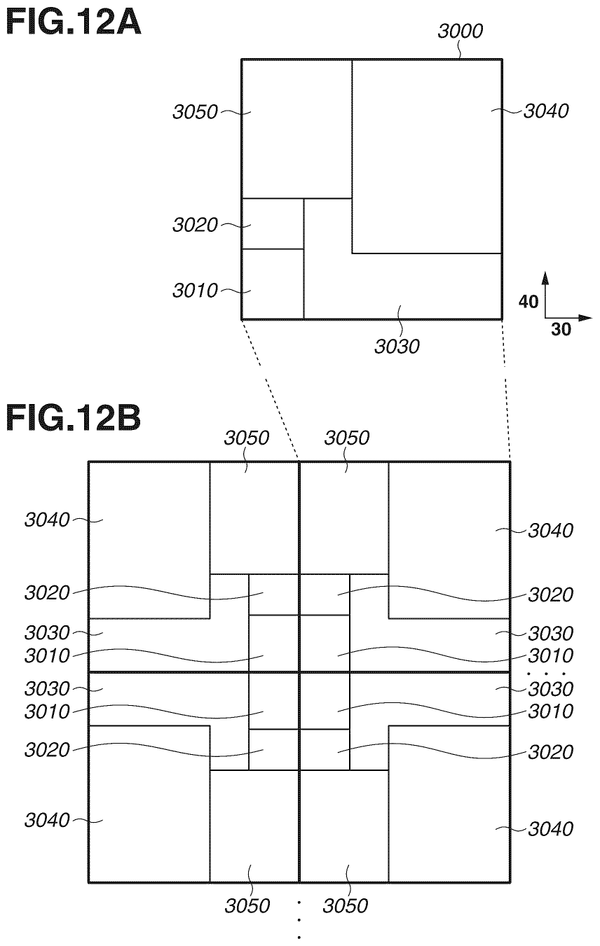

FIG. 12A illustrates a layout example of the quenching element 3010 and the waveform shaping circuit 3020 included in a pixel circuit 3000 corresponding to a pixel. FIG. 12A also illustrates a layout example of the processing circuit 3030, the counter circuit 3040, and the output circuit 3050. The quenching element 3010 (e.g., MOS transistor, therefore also referred to as a quenching circuit), the counter circuit 3040, and the output circuit 3050 are each located to adjoin pixel edges each. In other words, these circuits are located in contact with a border between a first pixel and a second pixel adjoining the first pixel. Here, “being in contact” does not refer strictly to touching the pixel edge or the border between the pixels but means that there is no circuit having another function between the adjoining pixels. For example, the foregoing configuration means that one of the quenching element 3010, the counter circuit 3040, and the output circuit 3050 is the closest circuit in the pixel circuit 3000 of the first pixel to the pixel circuit 3000 of the second pixel.

Such a layout of the pixel circuit 3000 facilitates supplying current to an element or circuit of high current consumption in the pixel circuit 3000 of the first pixel from the wiring for supplying voltage to the pixel circuit 3000 of the second pixel. This enables stable current supply to the pixel circuits 3000.

In FIG. 12A, the quenching element 3010 and the waveform shaping circuit 3020 are located to adjoin each other. As illustrated in FIG. 4, one of the nodes of the MOS transistor that is the quenching element 3010 is electrically connected to the input node of the waveform shaping circuit 3020. To enjoy the advantage of reduced wiring capacitance, the quenching element 3010 and the waveform shaping circuit 3020 are thus located close to each other even in terms of layout.

FIG. 12B illustrates a layout example of pixel circuits 3000 corresponding to four pixels. The pixels circuits 3000 of the respective pixels are arranged in a mirror layout. Circuits having the same functions in the pixel circuits 3000 of the respective pixels are thereby located to adjoin each other. For example, if a first pixel (top right pixel) and a second pixel (not illustrated) adjoin in the first direction 30, the counter circuits 3040 of the first and second pixels adjoin each other. If it is assumed that the top left pixel is a first pixel and the top right pixel is a second pixel, the quenching elements 3010 and the waveform shaping circuits 3020 of the first and second pixels adjoin each other. The circuits can thus be laid out in a space-saving manner.

Specifically, in FIG. 12A, the quenching element 3010 is located at a corner of the region where the pixel circuit 3000 is disposed. The corner here refers to that formed between a first side of the region including the pixel circuit 3000 in the first direction 30 and a second side of the region in the second direction 40. The corner also means that the region including the pixel circuit 3000 corresponding to a pixel is defined by a side in the first direction 30 and a side in the second direction 40, and the quenching element 3010 is located within ⅓ the lengths of the respective sides. For example, in FIG. 12A, the quenching element 3010 is located laterally within ⅓ of the length of the side from the bottom left vertex and vertically within ⅓ of the length of the side from the bottom left vertex.

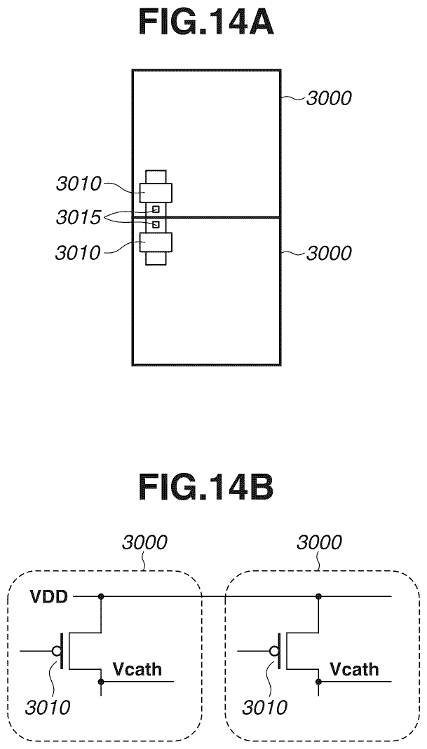

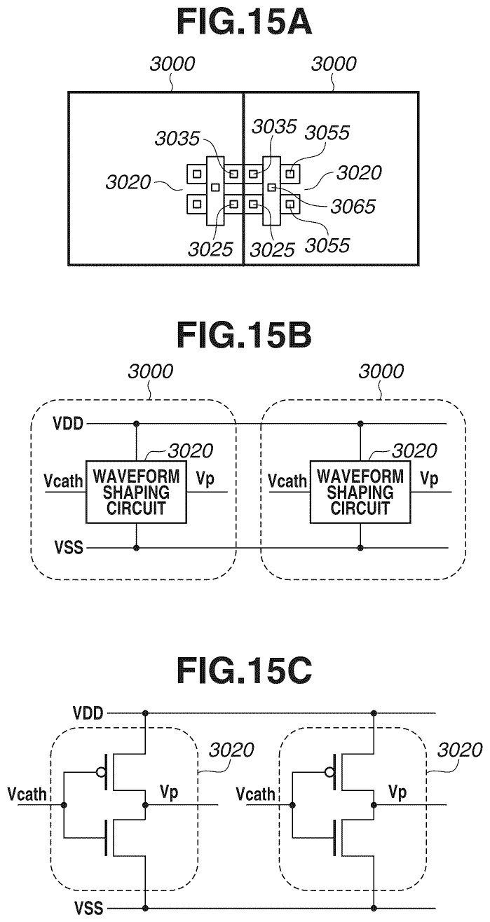

Suppose, for example, that the quenching element 3010 is a PMOS transistor and the transistors constituting the other circuits are NMOS transistors as illustrated in FIG. 4. In such a case, the PMOS transistor and the NMOS transistors desirably have well structures of different conductivity types. According to the layout example of FIG. 12B, however, the quenching elements 3010 of the four pixels can be located together. This enables the four pixels to share the N-well structure for the quenching elements 3010. As will be described below with reference to FIGS. 14A, 14B, and 15A to 15C, circuits can also be laid out such that diffusion regions and power supply wiring (e.g., contact wiring) are shared by a plurality of pixels.

### (Layout Example of Counter Circuits)

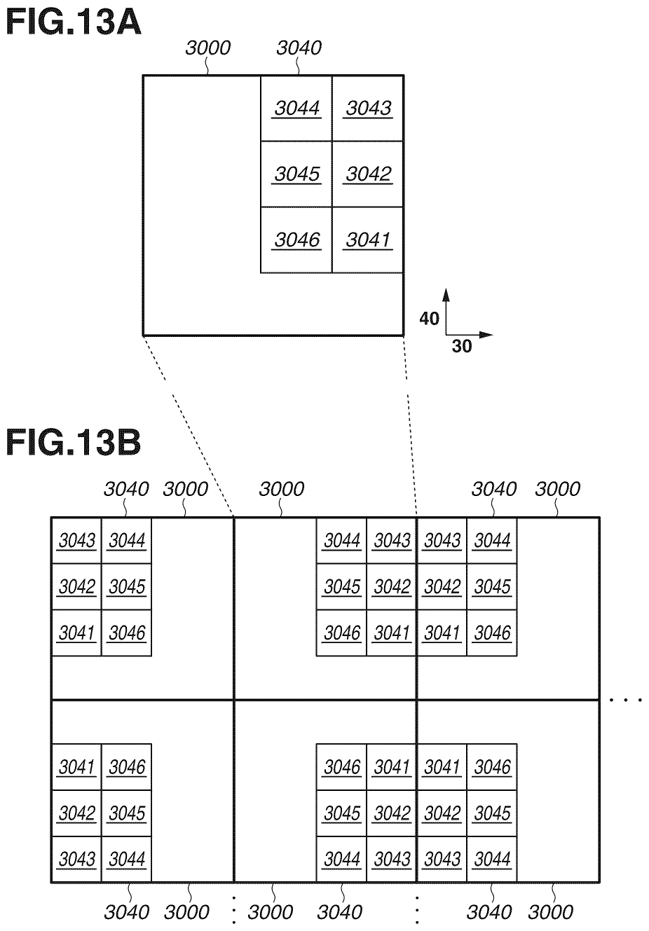

FIG. 13A illustrates a pixel circuit 3000 corresponding to a pixel. Focusing attention on the counter circuit 3040, the circuits other than the counter circuit 3040 are omitted. The counter circuit 3040 includes a first-bit circuit 3041, a second-bit circuit 3042, a third-bit circuit 3043, a fourth-bit circuit 3044, a fifth-bit circuit 3045, and a sixth-bit circuit 3046. Since the counter circuit 3040 is a six-bit counter, the first bit is the least significant bit (LSB) and the sixth bit is the most significant bit (MSB).

As illustrated in FIGS. 12A and 12B, the counter circuit 3040 occupies a larger area than any other circuit in the pixel circuit 3000. The first- to sixth-bit circuits 3041 to 3046 of the counter circuit 3040 are desirably continuously arranged for the purpose of signal processing. As illustrated in FIGS. 13A and 13B, the circuits constituting the counter circuit 3040 are thus arranged to fold back for the sake of space saving of the pixel circuit 3000. Specifically, the first-, second-, and third-bit circuits 3041, 3042, and 3043 are arranged in this order in the second direction 40. The fourth-bit circuit 3044 adjoins the third-bit circuit 3043 in the first direction 30. The fourth-, fifth-, and sixth-bit circuits 3044, 3045, and 3046 are arranged in this order in the direction opposite to the second direction 40.

If these circuits are linearly laid out without folding back as described above, the pixel circuit 3000 occupies a region of vertically or horizontally long shape. This can complicate the wiring layout between a plurality of photoelectric conversion units 102 disposed on a first substrate 11 and the pixel circuits 3000 disposed to correspond to the photoelectric conversion units 102. By contrast, the layout illustrated in FIG. 13A can save space of the pixel circuit 3000 and prevent complication of the wiring layout for electrically connecting the plurality of photoelectric conversion units 102 and the corresponding pixel circuits 3000.

FIG. 13B illustrates an example where pixel circuits 3000 of two rows and three columns, i.e., a total of six pixels are laid out. In other words, FIG. 13B illustrates the layout where a third column is added to the pixel circuits 3000 of the two rows and two columns, i.e., a total of four pixels illustrated in FIG. 12B.

Now, the first-row second-column pixel circuit 3000 (pixel circuit of a first pixel) and the first-row third-column pixel circuit 3000 (pixel circuit of a second pixel) in FIG. 13B will be focused. The counter circuit 3040 of the first pixel is located in contact with edges of the first pixel, and the counter circuit 3040 of the second pixel is located in contact with edges of the second pixel. More specifically, the counter circuits 3040 of the first and second pixels are located in contact with the border between the first and second pixels. As mentioned above, “being in contact” does not refer strictly to touching the pixel edge or the border between the pixels but means that there is no circuit having another function between the adjoining pixels. For example, “being in contact” means that there is no circuit other than the counter circuits 3040 between the counter circuit 3040 of the first pixel and the counter circuit 3040 of the second pixel.

In FIG. 13B, the shortest distance between the first-bit circuit 3041 (LSB) of the first pixel and the first-bit circuit 3041 (LSB) of the second pixel is smaller than that between the sixth-bit circuit 3046 (MSB) of the first pixel and the first-bit circuit 3041 (LSB) of the second pixel. In a counter circuit 3040, the LSB circuit 3041 is driven for a longer time than is the MSB circuit 3046, and the current consumption of the LSB circuit 3041 is higher than that of the MSB circuit 3046. If the current consumption of the LSB circuit 3041 of the first pixel is high, current can thus be supplied to the pixel circuit 3000 of the first pixel from the power supply wiring of the pixel circuit 3000 of the second pixel. By contrast, the current consumption of the MSB circuit 3046 of the first pixel is not high relative to that of the LSB circuit 3041, and such measures are not necessarily needed.

The layout illustrated in FIG. 13B can be described as follows: The counter circuit 3040 of the first pixel and the counter circuit 3040 of the second pixel adjoining the first pixel are arranged in a mirror symmetrical (line-symmetrical) manner. The LSB circuit 3041 of the first pixel and the LSB circuit 3041 of the second pixel are also arranged in a mirror symmetrical manner. The shortest distance between the LSB circuit 3041 of the first pixel and the LSB circuit 3041 of the second pixel is smaller than that between the MSB circuit 3046 of the first pixel and the MSB circuit 3046 of the second pixel. Satisfying such a relationship enables more stable current supply to the pixel circuits 3000.

A fourth exemplary embodiment describes a layout in a case where the quenching element 3010 in the pixel circuit 3000 described with reference to FIG. 4 is constituted by a MOS transistor and a layout in a case where the waveform shaping circuit 3020 is constituted by an inverter.

### (Layout Example of Quenching Elements)

FIG. 14A is a layout diagram of the pixel circuits 3000 of two pixels in a plan view. Focusing attention on the quenching elements 3010, the circuits other than the quenching elements 3010 are omitted. The first-row first-column circuit will be referred to as the pixel circuit 3000 of a first pixel. The second-row first-column circuit will be referred to as the pixel circuit 3000 of a second pixel. The pixel circuit 3000 of the first pixel and the pixel circuit 3000 of the second circuit are arranged in a mirror symmetrical (line-symmetrical) manner.

FIG. 14B is a circuit diagram of the quenching elements 3010 of the first and second pixels. As can be seen, the voltage VDD (second voltage) is supplied to the sources of the PMOS transistors constituting the quenching elements 3010 of the two pixels in common.

Return to FIG. 14A. The MOS transistor that is the quenching element 3010 of the first pixel and the MOS transistor that is the quenching element 3010 of the second pixel share an active region. Specifically, the diffusion region at the sources of the PMOS transistors that are the quenching elements 3010 is shared, and two contacts 3015 are disposed in the diffusion region. The voltage VDD (second voltage) is supplied to the contacts 3015, whereby the voltage VDD (second voltage) is also supplied to the sources of the PMOS transistors that are the quenching elements 3010.

With such a configuration, the diffusion region at the sources or drains of the MOS transistors (drains in the case of NMOS transistors) serving as the quenching elements 3010 can be shared by the pixel circuits 3000 of the two pixels. This can save space of the pixel circuits 3000.

In the foregoing description, the two contacts 3015 are described to be connected to the shared diffusion region. However, the number of contacts 3015 may be one. Alternatively, three or more contacts may be disposed. Sharing a contact by two pixels can simplify the layout.

### (Layout Example of Waveform Shaping Circuits)

FIG. 15A is a layout diagram of the pixel circuits 3000 of two pixels in a plan view. Focusing attention on the waveform shaping circuits 3020, the circuits other than the waveform shaping circuits 3020 are omitted. The first-row first-column circuit will be referred to as the pixel circuit 3000 of a first pixel. The first-row second-column circuit will be referred to as the pixel circuit 3000 of a second pixel. The pixel circuit 3000 of the first pixel and the pixel circuit 3000 of the second pixel are arranged in a mirror symmetrical (line-symmetrical) manner.

FIG. 15B is a circuit diagram of the waveform shaping circuits 3020 of the first and second pixels. As can be seen, the voltage VDD (second voltage) is supplied to one of the power supply nodes of each of the waveform shaping circuits 3020 of the two pixels in common. The voltage VSS (third voltage) is supplied to the other power supply nodes of the waveform shaping circuits 3020 of the two pixels in common.

FIG. 15C illustrates a detailed circuit diagram of FIG. 15B. The waveform shaping circuits 3020 are each constituted by an inverter circuit including a PMOS transistor and an NMOS transistor, with an input node Vcath and an output node Vp.

Return to FIG. 15A, and focus attention on the pixel circuit 3000 of the second pixel located in the first row and the second column. The waveform shaping circuit 3020 included in the pixel circuit 3000 of the second pixel includes two transistors. One and the other of the transistors have a common gate. A contact 3065 is connected to the gate. An input voltage Vcath of the waveform shaping circuit 3020 is supplied to the contact 3065. A contact 3035 and a contact 3055 are connected to the source and drain of one of the transistors illustrated in FIG. 15A (e.g., NMOS transistor), respectively. Similarly, a contact 3025 and a contact 3055 are connected to the source and drain of the other transistor (e.g., PMOS transistor), respectively. The voltage VSS (third voltage) is supplied to the contact 3035. The voltage VDD (second voltage) is supplied to the contact 3025. A voltage Vp is output from the contacts 3055.

As illustrated in FIG. 15A, the contact 3035 of the waveform shaping circuit 3020 of the first pixel and the contact 3035 of the waveform shaping circuit 3020 of the second pixel are connected to a shared diffusion region.

Similarly, the contact 3025 of the waveform shaping circuit 3020 of the first pixel and the contact 3025 of the waveform shaping circuit 3020 of the second pixel are connected to a shared diffusion region.

With such a configuration, the diffusion regions that are the sources or drains of the transistors constituting the waveform shaping circuits 3020 can be shared by the pixel circuits 3000 of the two pixels. This enables space saving of the pixel circuits 3000.

In the foregoing configuration, the two contacts (e.g., two contacts 3025 or two contacts 3035) are described to be disposed in the shared diffusion region. However, such two contacts may be integrated into one and disposed in the shared diffusion region.

A fifth exemplary embodiment describes a configuration and wiring layout of a photoelectric conversion apparatus that performs clock driving for pileup prevention.

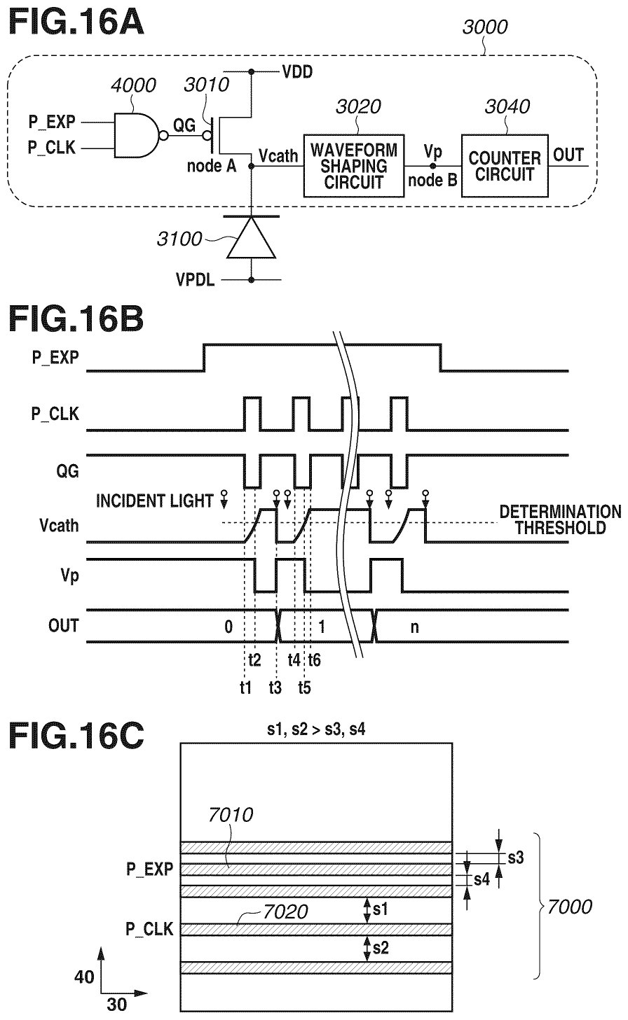

FIG. 16A illustrates an APD 3100 and a pixel circuit 3000 that are clock-driven. FIG. 16A illustrates, in the pixel circuit 3000, a quenching element 3010, a waveform shaping circuit 3020, a counter circuit 3040, and a signal generation circuit 4000, and the rest of the pixel circuit 3000 is omitted.

While a quenching operation and a recharge operation using the quenching element 3010 can be performed depending on avalanche multiplication in the APD 3100, the detection of a photon may not be determined as an output signal depending on the timing. For example, suppose a situation where the APD 3100 has caused avalanche multiplication, the input potential to node A has dropped to a low level, and a recharge operation is in progress. The determination threshold of the waveform shaping circuit 3020 is typically set to a potential higher than the potential that enables avalanche multiplication in the APD 3100. If the potential of node A is lower than the determination threshold due to the recharge operation and capable of avalanche multiplication in the APD 3100 when a photon is incident, the APD 3100 causes avalanche multiplication and the voltage of node A drops. Since the potential of node A drops from the potential lower than the determination threshold, the output potential from node B does not change despite the detection of the photon. In other words, the detection of the photon is not determined as a signal despite the occurrence of the avalanche multiplication. In particular, under high illuminance, photons are incident in succession in a short period of time and thus difficult to be determined as signals. This can lead to a discrepancy between the actual number of incident photons and the output signal despite high illuminance. Such a phenomenon may be referred to as a pileup phenomenon.

As illustrated in FIG. 16A, the quenching element 3010 constituted by a PMOS transistor is thus controlled on and off using a control signal QG, whereby photons incident on the APD 3100 in succession in a short time can be determined as signals.

The signal generation circuit 4000 is constituted by a logic circuit. The signal generation circuit 4000 here is constituted by a NAND circuit, to which a control signal P_EXP for controlling an exposure period and a control signal P_CLK are input. If the two input signals are “1”, the logic circuit outputs “0”. This output is the control signal QG. If either of the two input signals is “0”, the logic circuit outputs “1”. If the control signal QG is “0”, the quenching element 3010 that is a PMOS transistor turns on. If the control signal QG is “1”, the quenching element 3010 that is a PMOS transistor turns off.

Referring to the pulse diagram of FIG. 16B, if the control signal P_EXP is at a high level and the control signal P_CLK becomes high, the control signal QG becomes low and the PMOS transistor that is the quenching element 3010 turns on. With the quenching element 3010 on, the resistance of the PMOS transistor decreases and a recharge operation is performed. On the other hand, if either of the control signals P_EXP and P_CLK is at a low level, the control signal QG becomes high and the PMOS transistor that is the quenching element 3010 turns off. With the quenching element 3010 off, the resistance of the PMOS transistor increases and a recharge operation becomes difficult to occur. The avalanche multiplication operation of the APD 3100 thus stops.

At time t1, the control signal QG transitions from the high level to the low level, the quenching element 3010 turns on, and the recharge operation of the APD 3100 is started. As a result, the potential (voltage) Vcath at the cathode of the APD 3100 (node A) transitions to the high level. The potential difference between the potentials applied to the anode and cathode of the APD 3100 becomes a level capable of avalanche multiplication. The potential Vcath reaches or exceeds the determination threshold at time t2 in transitioning from the low level to the high level. Here, the pulse signal output from the output node Vp (node B) is reversed from the high level to the low level. A potential difference that enables avalanche multiplication is then applied to the APD 3100. The control signal QG transitions from the low level to the high level, and the switch (quenching element 3010) turns off.

At time t3, a photon is incident on the APD 3100. The APD 3100 causes avalanche multiplication, an avalanche multiplication current flows through the quenching element 3010, and the voltage Vcath drops. When the amount of voltage drop increases further and the voltage difference applied across the APD 3100 decreases, the avalanche multiplication of the APD 3100 stops as with time t2, and the voltage level of the input node Vcath stops dropping beyond a certain value. When the dropping voltage Vcath falls below the determination threshold, the voltage Vp changes from the low level to the high level. In other words, the portion of the output waveform at the input node Vcath exceeding the determination threshold is shaped by the waveform shaping circuit 3020 and output as a pulse signal from node B. The pulse signal is counted by the counter circuit 3040, and the count of the pulse signal output from the counter circuit 3040 increases by one LSB.

There is a photon incident on the APD 3100 between times t3 and t4, whereas the control signal QG is at the high level and the quenching element 3010 is off, and the voltage applied to the APD 3100 does not provide a potential difference capable of avalanche multiplication. The voltage level of the input node Vcath therefore does not exceed the determination threshold.

At time t4, the control signal QG changes from the high level to the low level, and the quenching element 3010 turns on. As a result, a current compensating for the voltage drop flows through the input node Vcath, and the voltage of the input node Vcath transitions to the original voltage level. At time t5, the voltage of the input node Vcath reaches or exceeds the determination threshold, and the pulse signal from the output node Vp is reversed from high level to the low level.

At time t6, the input node Vcath settles at the original voltage level, and the control signal QG changes from the low level to the high level. The quenching element 3010 thus turns off. Subsequently, the potentials at the nodes and signal lines change as described from time t1 to time t6, depending on the control signal QG and the incidence of photons.

As described above, the recharge operation is performed at predetermined periods by the control signal QG. Photons are not counted during un-recharged periods. Even if photons are incident in succession in a short period of time, one of the photons is thus determined as a signal and the others are not counted. For example, in the example of FIG. 16B, the photon incident at time t3 is counted, and the photon incident between times t3 and t4 is not. If the control signal QG is clock-driven as illustrated in FIG. 16B, the number of times the control signal QG becomes low in a predetermined exposure period where the control signal P_EXP is at the high level is the upper limit of the number of photons that can be counted. Such a configuration can reduce the phenomenon that the actual number of incident photons and the output signal tend to be discrepant despite high illuminance.

FIG. 16C is a diagram illustrating the layout of a signal wiring group 7000 including a trace for transmitting the control signal P_EXP and a trace for transmitting the control signal P_CLK. FIG. 16C illustrates a predetermined wiring layer extracted from the wiring layers for the pixel circuit of a single pixel in a plan view. A trace 7010 for the control signal P_EXP and a trace 7020 for the control signal P_CLK are disposed to extend in the first direction 30. Although not denoted by reference numerals, other traces are also disposed to extend in the first direction 30.

As illustrated in FIG. 16B, the control signal P_CLK transitions a plurality of times while the control signal P_EXP is at the high level. The frequency of the control signal P_CLK is thus higher than that of the control signal P_EXP. Considering capacitive coupling between traces, the distance between a trace of high frequency and a trace adjoining the trace is desirably greater than that between a trace of low frequency and a trace adjoining the trace. Specifically, the distance between the trace for the control signal P_CLK and a trace adjoining the trace is desirably greater than that between the trace for the control signal P_EXP and a trace adjoining the trace.

FIG. 16C is a layout diagram of control signal traces and other signal traces. The distances between the trace 7020 for the control signal P_CLK and the traces adjoining the trace 7020 are s1 and s2. The distances between the trace 7010 for the control signal P_EXP and the traces adjoining the trace 7010 are s3 and s4. The relationships s1>s3 and s1>s4 and the relationships s2>s3 and s2>s4 are both satisfied. Such layout of the control signal traces on the wiring layer can reduce capacitive coupling between the traces and reduce the effect of the switching on and off of the control signal P_CLK on the other traces.

In a sixth exemplary embodiment, like the fifth exemplary embodiment, a configuration and wiring layout of a clock-driven photoelectric conversion apparatus will be described.

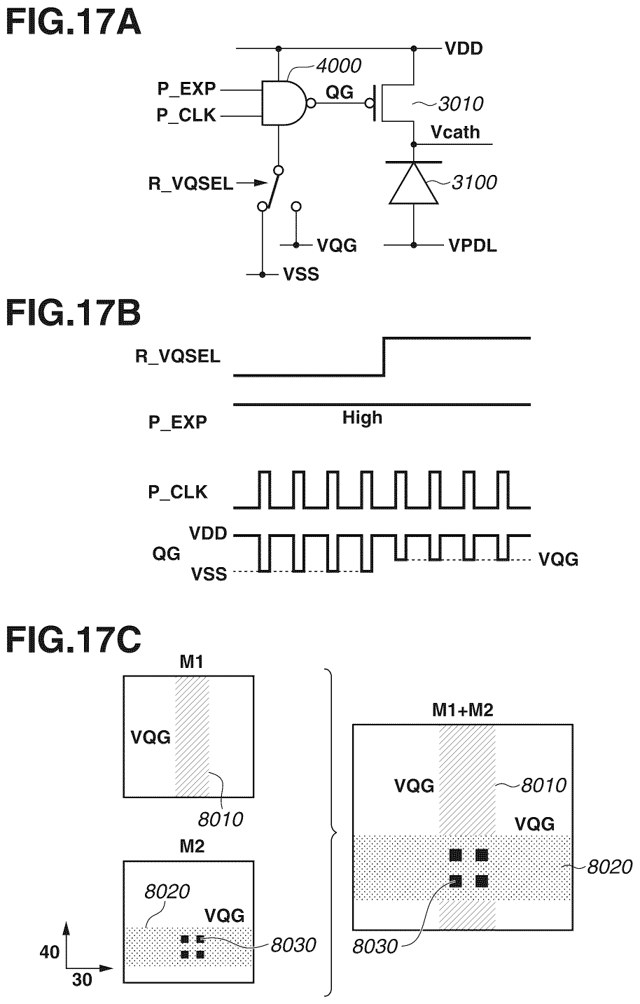

FIG. 17A illustrates an example of the clock-driven circuits. A description of circuits similar to those of the fifth exemplary embodiment will be omitted. The waveform shaping circuit and the counter circuit are similar to those of FIGS. 16A to 16C and are therefore omitted in the diagram.

A comparison between FIGS. 17A and 16A shows that a power supply voltage input to the signal generation circuit 4000 in FIG. 17A can be selected between the voltage VSS (third voltage) and a voltage VQG (fourth voltage). The voltage VSS (third voltage) and the voltage VQG (fourth voltage) are switched by a control signal R_VQSEL. This control signal R_VQSEL can make the low-level voltage of the control signal QG variable.

The pulse diagram of FIG. 17B is an extraction from the pulse diagram of FIG. 16B, where the control signal P_EXP is at the high level. In FIG. 17B, if the control signal R_VQSEL is at the low level, the signal generation circuit 4000 is connected to the voltage VSS (third voltage). Since the control signal P_EXP is at the high level, the control signal QG becomes high and the PMOS transistor that is the quenching element 3010 turns off when the control signal P_CLK is at the low level. The high-level voltage of the control signal QG is VDD (second voltage). On the other hand, when the control signal P_CLK is at the high level, the control signal QG becomes low and the PMOS transistor that is the quenching element 3010 turns on since the control signal P_EXP is at the high level. The low-level voltage of the control signal QG is VSS (third voltage).

The control signal R_VQSEL then transitions from the low level to the high level. In such a case, the high-level voltage of the control signal QG is the same as the foregoing, i.e., VDD (second voltage), whereas the low-level voltage of the control signal QG becomes VQG (fourth voltage).

Since the voltage input to the gate of the quenching element 3010 that is a PMOS transistor is variable, the quenching element 3010 changes in resistance. Specifically, the resistance of the quenching element 3010 when the voltage VSS (third voltage) is applied to the gate is lower than that of the quenching element 3010 when the voltage VQG (fourth voltage) is applied to the gate. The recharge time when the gate voltage is set to the voltage VSS (third voltage) is thus shorter than that when the gate voltage is set to the voltage VQG (fourth voltage). For example, returning to FIG. 16B, the recharge operation on the input node Vcath is completed at timing when the control signal QG returns from the low level to the high level. If the value of the voltage VSS (third voltage) is low for the gate voltage of the quenching element 3010, the quenching element 3010 has a low resistance and the recharge time is short. In such a case, the recharge operation is completed before the control signal QG returns from the low level to the high level. If a photon is incident at such timing, avalanche multiplication occurs. The recharge operation is then completed again before the control signal QG returns from the low level to the high level, and second avalanche multiplication can occur due to the incident of another photon. That is, in such a case, avalanche multiplication occurs twice before the control signal QG returns from the low level to the high level. In other words, avalanche multiplication occurs twice or more for a single pulse of the control signal P_CLK, with needless power consumption. Such a phenomenon can occur under high illuminance in particular. Making the recharge time variable thus has an advantage of averaging the power consumption in a predetermined exposure period, and as a result, reducing the power consumption.

In FIG. 17B, the voltage VSS (third voltage) and the voltage VQG (fourth voltage) are switched within an exposure period. However, the voltage VSS (third voltage) may be set during a first exposure period, and the voltage VQG (fourth voltage) during a second exposure period different from the first exposure period. Alternatively, light detection may be performed using only the voltage VSS (third voltage) or using only the voltage VQG (fourth voltage), depending on a mode setting.

FIG. 17C is a layout diagram of wiring for supplying the voltage VQG in a region where the pixel circuit of a single pixel is disposed. As described above, the voltage VQG serves as a voltage for determining the recharge time. To reduce the effects of other signal wiring, a wiring layout for reduced resistance is therefore desirably employed. Specifically, two-dimensional wiring or a large wiring width in a plan view may be employed. However, as described above, APD sensors including SPADs include a large number of circuits constituting pixel circuits provided pixel by pixel. APD sensors thus include a large number of power supply lines to the circuits and a large number of input and output lines to/from the circuits, and have a high wiring density between the circuits. The higher the wiring density, the more likely the wiring for low-resistance applications is to be divided and the more difficult the wiring is to two-dimensionally lay out on a single wiring layer. Moreover, the higher the wiring density, the more difficult it is to secure a space for increasing the wiring width.

As illustrated in FIG. 17C, a trace 8010 of the voltage VQG (fourth voltage) is thus extended in the second direction 40 on a first wiring layer (M1). The trace 8010 is disposed to reach both ends of the region including the pixel circuit of a single pixel. Moreover, a trace 8020 of the voltage VQG (fourth voltage) is extended in the first direction 30 on a second wiring layer (M2). The trace 8020 is also disposed to reach both ends of the region. The traces 8010 and 8020 are electrically connected by vias 8030. The power supply wiring can thereby be two-dimensionally laid out, and the effects of the other wiring can be reduced to enable a stable recharge operation.

The proportion of the area of the wiring for supplying the voltage VQG (fourth voltage) on the wiring layer of the region including the pixel circuit of a single pixel is ⅕ or more, for example. Such a large wiring width can lower the resistance, and the effects of the other wiring can be reduced to enable a stable recharge operation.

In the foregoing description, the wiring for supplying the voltage VGQ (fourth voltage) is disposed on the first wiring layer (M1) and the second wiring layer (M2). However, the wiring may be disposed on other wiring layers. For example, as illustrated in FIGS. 11A to 11I, the wiring of the voltages VSS and VDD is two-dimensionally laid out by combining the first wiring layer (M1) to the third wiring layer (M3). The wiring of the voltage VQG may then be two-dimensionally laid out by combining the fourth wiring layer (M4) and the fifth wiring layer (M5).

### (First Modification)

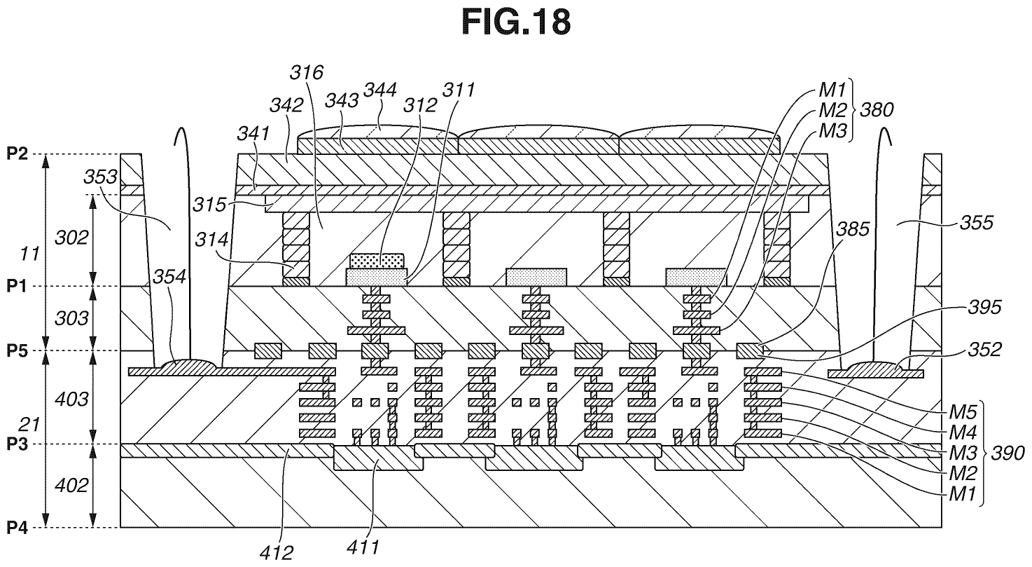

FIG. 18 is a sectional view of a modification of the photoelectric conversion apparatuses according to the foregoing plurality of exemplary embodiments. Parts common with those described with reference to FIG. 6 are denoted by the same reference numerals, and a description thereof will thus be omitted. The same applies to other modifications to be described below.

In the present modification, the positions of the first and second pad electrodes 352 and 354 are changed from those of FIG. 6.

In FIG. 6, one of the wiring layers of the wiring structure 303, such as the third wiring layer, includes the first and second pad electrodes 352 and 354. In FIG. 18, one of the wiring layers of the wiring structure 403, such as the fifth wiring layer, includes the first and second pad electrodes 352 and 354. The first and second pad openings 353 and 355 have a depth greater than that of the first and second pad openings 353 and 355 illustrated in FIG. 6. As employed herein, a depth refers to a distance from the backside of the semiconductor layer 302, for example. The first and second pad electrodes 352 and 354 can be located between a fifth plane P5 and a fourth plane P4. For example, the first and second pad electrodes 352 and 354 are located between the fifth plane P5 and a third plane P3. The backside of the semiconductor layer 302 refers to the interface with the pinning layer 341, for example. The first and second pad openings 353 and 355 penetrate through the bonding surface and extend from the semiconductor layer 302. The photoelectric conversion apparatuses 100 according to the exemplary embodiments of the present invention may have such a configuration. While the first and second pad electrodes 352 and 354 are described to be included in a wiring layer, the pad electrodes 352 and 354 may be formed separately from the wiring layers.

### (Second Modification)

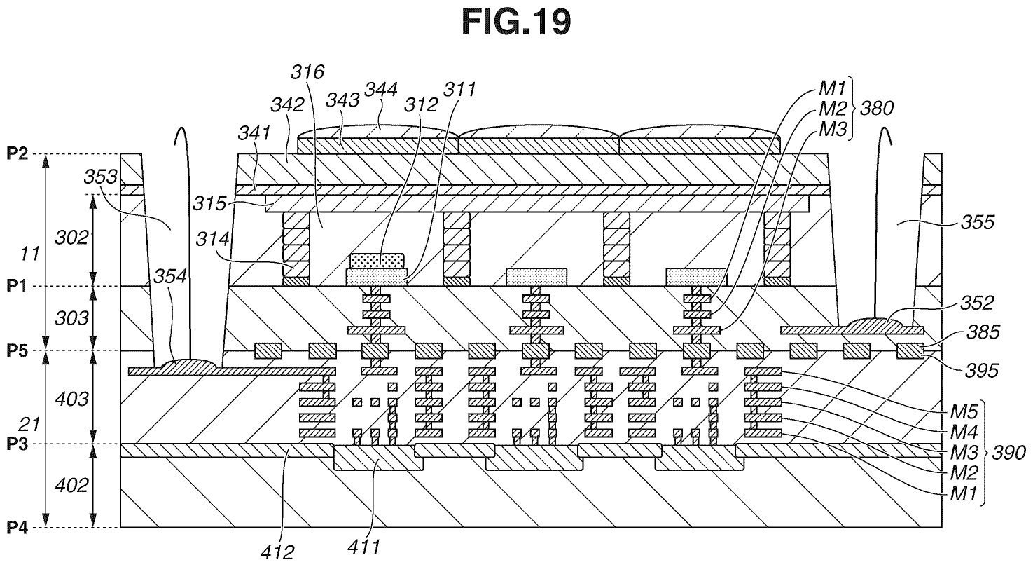

FIG. 19 illustrates a modification of a photoelectric conversion apparatus 100. FIG. 19 corresponds to the sectional view illustrated in FIG. 6. In this modification, the positions of the second pad electrodes 354 are changed from those of the configuration described with reference to FIG. 6.

In FIG. 6, one of the wiring layers of the wiring structure 303, such as the third wiring layer, includes the second pad electrodes 354. In FIG. 19, one of the wiring layers of the wiring layer 403, such as the fifth layer, includes the second pad electrodes 354. In other words, the second pad electrodes 354 may be located between the fifth plane P5 and the fourth plane P4. For example, the second pad electrodes 354 are located between the fifth plane P5 and the third plane P3. Alternatively, the second pad electrodes 352 can be located between a second plane P2 and the fifth plane P5. For example, the second pad electrodes 354 are located between a first plane P1 and the fifth plane P5. One of the wiring layers of the wiring structure 403 may include the first pad electrode 352, and one of the wiring layers of the wiring structure 303 the second pad electrodes 354. The photoelectric conversion apparatus 100 according to the present exemplary embodiment may have such a configuration.

While the first and second pad electrodes 352 and 354 are described to be included in wiring layers, the pad electrodes 352 and 354 may be formed separately from the wiring layers.

### (Third Modification)

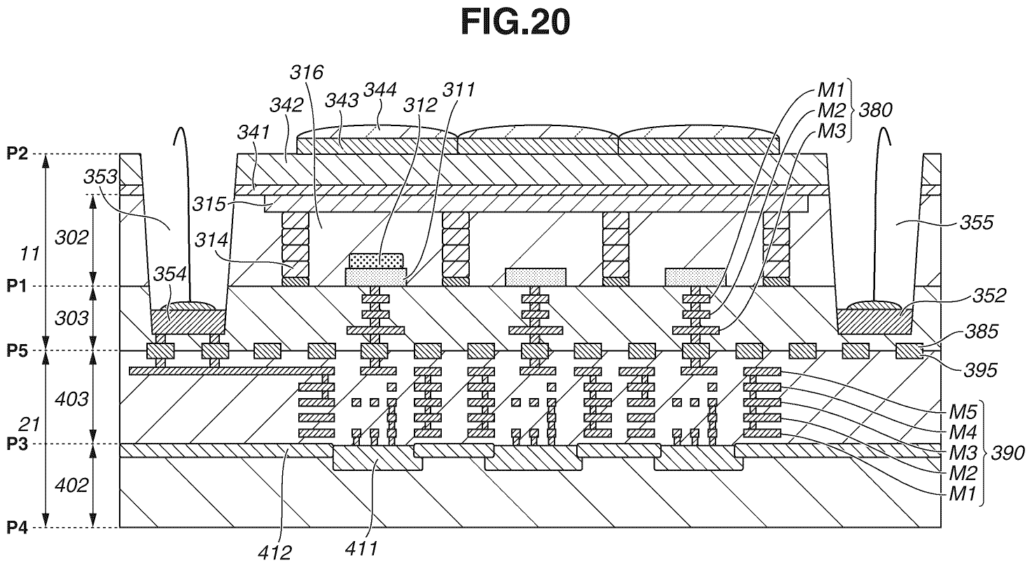

FIG. 20 illustrates a modification of a photoelectric conversion apparatus 100. FIG. 20 corresponds to the sectional view illustrated in FIG. 6. In this modification, the structures of the first and second pad electrodes 352 and 354 are changed from the configuration described with reference to FIG. 6.

The wiring structure 303 includes the first to third wiring layers M1 to M3 and the first bonding portions 385. The wiring structure 403 includes the first to fifth wiring layers M1 to M5 and the second bonding portions 395. Each wiring layer includes copper wiring.

In the wiring structures 303 and 403, the first wiring layers M1 include conductor patterns consisting mainly of copper. The conductor patterns of the first wiring layers M1 have a single damascene structure. There are contacts for electrically connecting the first wiring layer M1 of the wiring structure 303 and the semiconductor layer 302. The contacts are conductor traces consisting mainly of tungsten. The second and third wiring layers M2 and M3 include conductor patterns consisting mainly of copper. The conductor patterns of the second and third wiring layers M2 and M3 have a dual damascene structure and include portions functioning as wiring and portions functioning as vias. The fourth and upper wiring layers are similar to the second and third wiring layers M2 and M3.

The first and second pad electrodes 352 and 354 are conductor traces consisting mainly of aluminum. The first and second pad electrodes 352 and 354 are located across the second and third wiring layers M2 and M3 of the wiring structure 303. For example, the first and second pad electrodes 352 and 354 include portions functioning as vias connecting the first wiring layer M1 and the second wiring layer M2 and portions functioning as traces of the third wiring layer M3. The first and second pad electrodes 352 and 354 are located between the first plane P1 and the fifth plane P5, for example. The first and second pad electrodes 352 and 354 may be located between the second plane P2 and the fourth plane P4, or between the second plane P2 and the fifth plane P5.

The first and second pad electrodes 352 and 354 each have a first surface and a second surface opposite the first surface. A part of the first surface is exposed through an opening in the semiconductor layer 302.

The exposed portions of the first and second pad electrodes 352 and 354 can function as connection portions with external terminals, i.e., pad portions. The first and second pad electrodes 352 and 354 are connected at their second surfaces to a plurality of conductors consisting mainly of copper.

As an alternative form to the present modification, unexposed portions of the first surfaces of the first and second pad electrodes 352 and 354 may serve as electrical connection portions. For example, the first and second pad electrodes 352 and 354 may include conductor vias consisting mainly of aluminum and be electrically connected with the conductors consisting mainly of copper, located on the first surfaces may be established through the vias. The first and second pad electrodes 352 and 354 may be connected at their first surfaces to the first wiring layer M1 of the wiring structure 303 by conductors consisting mainly of tungsten.

The first and second pad electrodes 352 and 354 can be formed by the following procedure, for example. After the formation of the insulator covering the third wiring layer M3, the insulator is partly removed and a film consisting mainly of aluminum to be the first and second pad electrodes 352 and 354 is formed. The film can then be patterned into the first and second pad electrodes 352 and 354. Since the copper wiring is formed before the formation of the first and second pad electrodes 352 and 354, the first and second pad electrodes 352 and 354 with a large thickness can be formed while maintaining the flatness of the fine copper wiring.

In the present modification, the first and second pad electrodes 352 and 354 are described to be included in the wiring structure 303. However, the first and second pad electrodes 352 and 354 may be included in the wiring structure 403. The pad electrodes 352 and 354 may be located in either of the wiring structures 303 and 403 without any limitation. The materials and structures of the wiring layers in the wiring structures 303 and 403 are not limited to those described above. For example, additional conductor layers may be disposed between the first wiring layers M1 and the semiconductor layers 302 and 402. The contacts may have a two-layer stacked contact structure.

### (Fourth Modification)

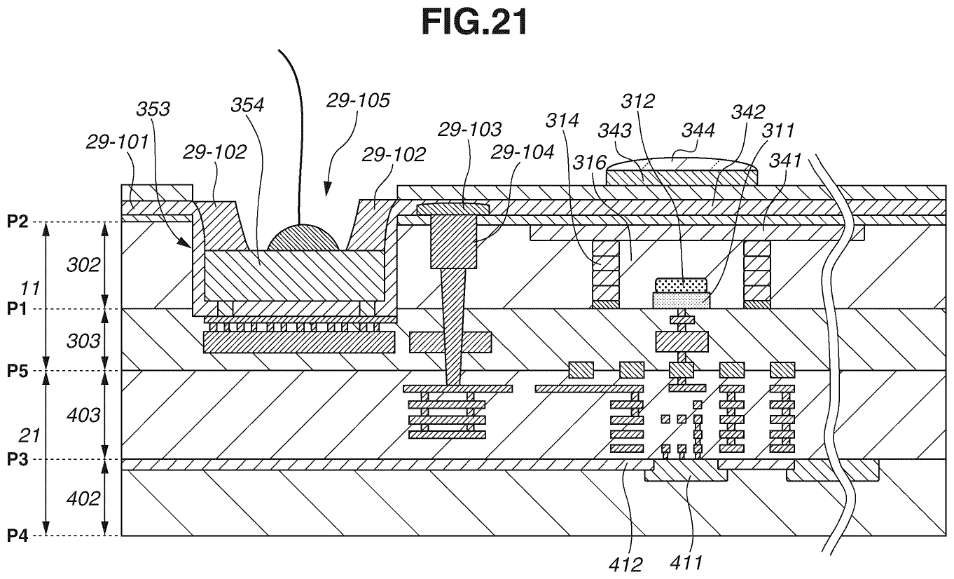

FIG. 21 illustrates a modification of a photoelectric conversion apparatus 100. FIG. 21 is an enlarged sectional view of the vicinity of the second pad electrode 354 illustrated in the sectional view of FIG. 6. In the present exemplary embodiment, the structure of the second pad electrode 354 is mainly changed from the configuration of the first exemplary embodiment.

The wiring structure 303 includes the first and second wiring layers M1 and M2 and the first bonding portions 385. The wiring structure 403 includes the first to fourth wiring layers M1 to M4 and the second bonding portions 395. Each wiring layer includes copper wiring.

In the wiring structures 303 and 403, the first wiring layers M1 include conductor patterns consisting mainly of copper. The conductor patterns of the first wiring layers M1 have a single damascene structure. There are contacts for electrically connecting the first wiring layer M1 of the wiring structure 303 and the semiconductor layer 302. The contacts are conductor traces consisting mainly of tungsten. The other wiring layers also include conductor traces consisting mainly of copper with a dual damascene structure and include portions functioning as wiring and portions functioning as vias.

The second pad electrode 354 is a conductive trace consisting mainly of aluminum. The second pad electrode 354 is disposed in an opening of the semiconductor layer 302, not in a wiring structure. While the second pad electrode 354 is illustrated to have an exposed surface between the second plane P2 and the first plane P1, the exposed surface of the second pad electrode 354 may be located above the second plane P2.

A method for forming this structure will be briefly described. The first pad opening 353 is formed in the semiconductor layer 302 such that a part of the first wiring layer M1 of the wiring structure 303 is exposed. An insulator 29-101 is formed to cover the second plane P2 of the semiconductor layer 302 and the first pad opening 353. Openings to be vias of the second pad electrode 354 are formed in the insulator 29-101. After a conductive film to be the second pad electrode 354 is formed, unnecessary portions of the conductive film are removed to form a predetermined pattern. An insulator 29-102 is further formed, and then an opening 29-105 to expose the second pad electrode 354 is formed. This structure can be formed in this way.

A through electrode 29-104 may also be formed from the second plane P2 side. The through electrode 29-104 may be made of a conductor consisting mainly of copper and include a barrier metal between the semiconductor layer 302 and the conductor.

On the through electrode 29-104, a conductor 29-103 is disposed. The conductor 29-103 may be common with other through electrodes. The conductor 29-103 may have a function of reducing the diffusion of the conductor of the through electrode 29-104.

The first pad electrode 352 (not illustrated) may have a configuration similar to that of the second pad electrode 354. The materials and structures of the wiring layers of the wiring structures 303 and 403 are not limited to those described above. For example, additional conductor layers may be disposed between the first wiring layers M1 and the semiconductor layers 302 and 402. The contacts may have a two-layer stacked contact structure.

While the first and second pad electrodes 352 and 354 are described to be located between the second plane P2 and the fourth plane P4, the first and second pad electrodes 352 and 354 may be located on the second plane P2.

The first and second pad openings 353 and 355 may be formed in the second substrate 21. If the first and second pad openings 353 and 355 are located in the second substrate 21, through electrodes may be formed in the openings. The electrical connection portions of the through electrodes with an external apparatus can be located on the fourth plane P4.

Pad electrodes serving as electrical connection portions with an external apparatus may be located on both the fourth plane P4 of the second substrate 21 and the second plane P2 of the first substrate 11.

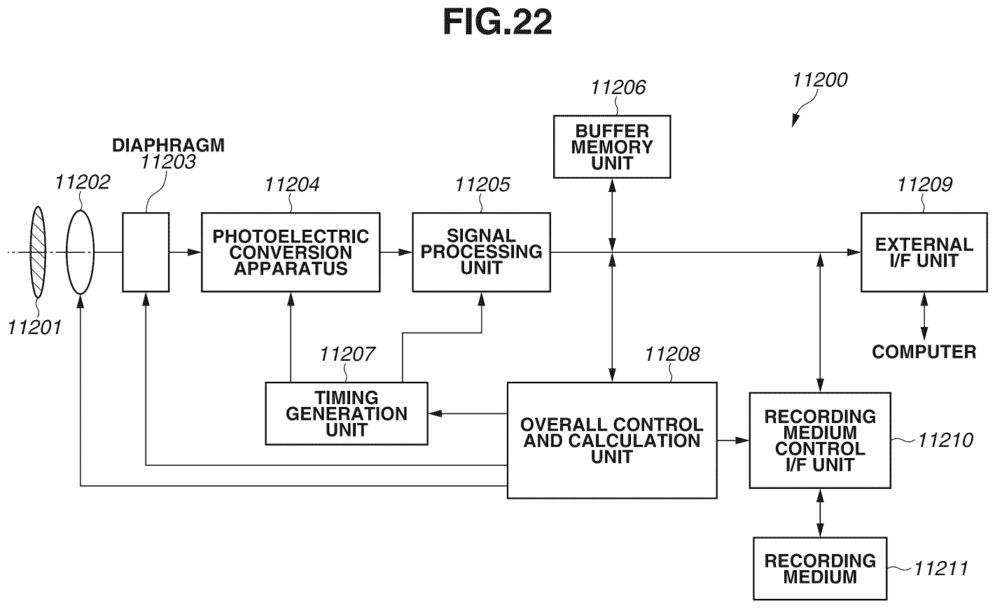

FIG. 22 is a block diagram illustrating a configuration of a photoelectric conversion system 11200 according to a seventh exemplary embodiment. The photoelectric conversion system 11200 according to the present exemplary embodiment includes a photoelectric conversion apparatus 11204. Any of the photoelectric conversion apparatuses described in the foregoing exemplary embodiments can be applied as the photoelectric conversion apparatus 11204. The photoelectric conversion system 11200 can be used as an imaging system, for example. Specific examples of the imaging system include a digital still camera, a digital camcorder, and a surveillance camera. FIG. 22 illustrates a digital still camera as an example of the photoelectric conversion system 11200.

The photoelectric conversion system 11200 illustrated in FIG. 22 includes the photoelectric conversion apparatus 11204 and a lens 11202 for forming an optical image of an object on the photoelectric conversion apparatus 11204. The photoelectric conversion system 11200 further includes a diaphragm 11203 for adjusting the amount of light passing through the lens 11202 and a barrier 11201 for protecting the lens 11202. The lens 11202 and the diaphragm 11203 constitute an optical system for collecting light to the photoelectric conversion apparatus 11204.

The photoelectric conversion system 11200 includes a signal processing unit 11205 that processes an output signal output from the photoelectric conversion apparatus 11204. The signal processing unit 11205 performs a signal processing operation for performing various types of correction and compression on the input signal as appropriate and outputting the resulting signal. The photoelectric conversion system 11200 further includes a buffer memory unit 11206 for temporarily storing image data and an external interface (I/F) unit 11209 for communicating with an external computer. The photoelectric conversion system 11200 further includes a recording medium 11211, such as a semiconductor memory, for recording or reading captured image, and a recording medium control I/F unit 11210 for recording or reading the captured data on/from the recording medium 11211. The recording medium 11211 may be built in the photoelectric conversion system 11200, or detachably attachable to the photoelectric conversion system 11200. The communication between the recording medium control I/F unit 11210 and the recording medium 11211 and the communication from the external I/F unit 11209 may be wirelessly performed.

The photoelectric conversion system 11200 further includes an overall control and calculation unit 11208 that performs various types of calculation and controls the entire digital still camera, and a timing generation unit 11207 that outputs various timing signals to the photoelectric conversion apparatus 11204 and the signal processing unit 11205. The timing signals may be input from outside, and the photoelectric conversion system 11200 can include at least the photoelectric conversion apparatus 11204 and the signal processing unit 11205 that processes the output signal output from the photoelectric conversion apparatus 11204. The overall control and calculation unit 11208 and the timing generation unit 11207 may be configured to perform some or all of control functions of the photoelectric conversion apparatus 11204.

The photoelectric conversion apparatus 11204 outputs an image signal to the signal processing unit 11205. The signal processing unit 11205 performs predetermined signal processing on the image signal output from the photoelectric conversion apparatus 11204, and outputs image data. The signal processing unit 11205 generates an image using the image signal. The signal processing unit 11205 may perform distance measurement calculation on the signal output from the photoelectric conversion apparatus 11204. The signal processing unit 11205 and the timing generation unit 11207 may be included in the photoelectric conversion apparatus 11204. In other words, the signal processing unit 11205 and the timing generation unit 11207 may be disposed on a substrate where pixels are disposed or another substrate. Configuring the imaging system using the photoelectric conversion apparatuses according to the foregoing exemplary embodiments can implement an imaging system capable of acquiring images of high quality.

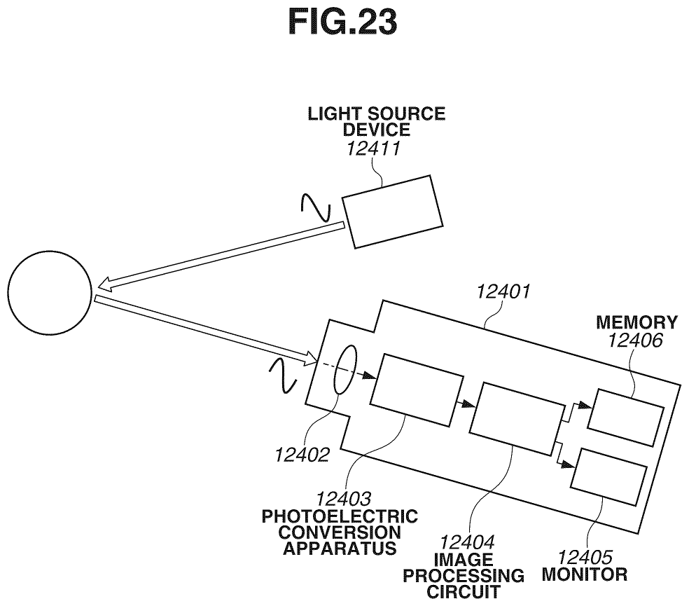

FIG. 23 is a block diagram illustrating a configuration example of a distance image sensor according to an eighth exemplary embodiment, which is an electronic device using any of the photoelectric conversion apparatuses according to the foregoing exemplary embodiments.

As illustrated in FIG. 23, a distance image sensor 12401 includes an optical system 12402, a photoelectric conversion apparatus 12403, an image processing circuit 12404, a monitor 12405, and a memory 12406. The distance image sensor 12401 can acquire a distance image according to a distance to an object by receiving light (modulated light or pulsed light) projected upon the object from a light source device 12411 and reflected at the surface of the object.

The optical system 12402 includes one or more lenses. The optical system 12402 guides image light (incident light) from the object to the photoelectric conversion apparatus 12403 so that the image light is focused on the light receiving surface (sensor unit) of the photoelectric conversion apparatus 12403.

Any one of the photoelectric conversion apparatuses according to the foregoing exemplary embodiments is applied as the photoelectric conversion apparatus 12403. A distance signal indicating a distance, determined from a light reception signal output from the photoelectric conversion apparatus 12403, is supplied to the image processing circuit 12404.

The image processing circuit 12404 performs image processing for constructing a distance image based on the distance signal supplied from the photoelectric conversion apparatus 12403. The distance image (image data) obtained by the image processing is then supplied to and displayed on the monitor 12405 or supplied to and stored (recorded) in the memory 12406.

The distance image sensor 12401 having such a configuration can acquire, for example, an accurate distance image, since the application of the foregoing photoelectric conversion apparatus improves the pixel characteristics.

A technique (present technique) according to a ninth exemplary embodiment of the present invention can be applied to various products. For example, the technique according to the present exemplary embodiment may be applied to an endoscopic surgery system.

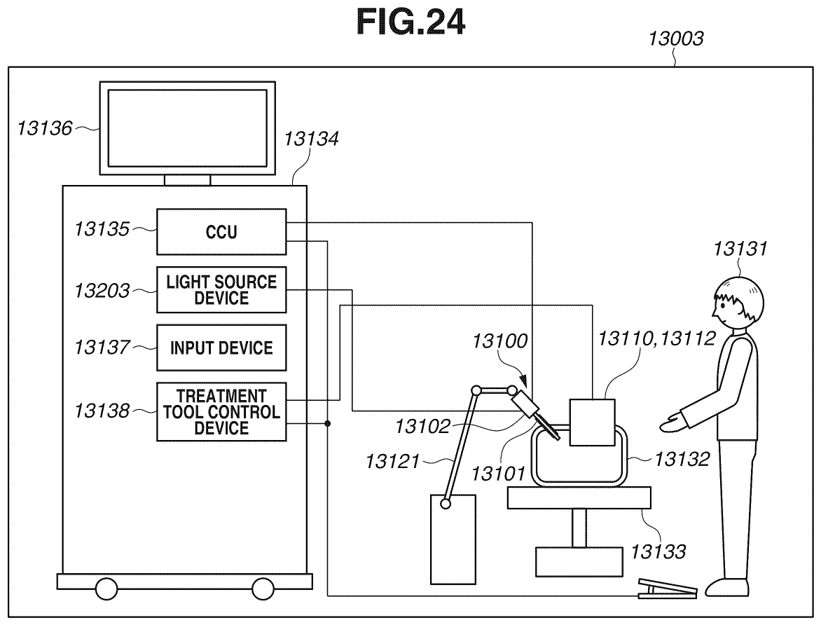

FIG. 24 is a diagram illustrating an example of a schematic configuration of an endoscopic surgery system to which the technique (present technique) according to the present exemplary embodiment can be applied.

FIG. 24 illustrates a state where an operator (doctor) 13131 is performing surgery on a patient 13132 on a patient bed 13133 using an endoscopic surgery system 13003. As illustrated in the diagram, the endoscopic surgery system 13003 includes an endoscope 13100, a surgical tool 13110, and a cart 13134 on which various devices for endoscopic surgery are mounted.

The endoscope 13100 includes a lens barrel 13101 and a camera head 13102. A predetermined length of the lens barrel 13101 of its tip is inserted into a body cavity of the patient 13132. The camera head 13102 is connected to the bottom end of the lens barrel 13101. In the illustrated example, the endoscope 13100 is illustrated to be configured as a rigid scope with a rigid lens barrel 13101. However, the endoscope 13100 may be configured as a flexible scope having a flexible lens barrel.

The tip of the lens barrel 13101 has an opening with an objective lens fitted thereto. A light source device 13203 is connected to the endoscope 13100. Light generated by the light source device 13203 is guided to the tip of the lens barrel 13101 by a lightguide extended through the lens barrel 13101. The light is emitted toward an observation target in the body cavity of the patient 13132 through the objective lens. The endoscope 13100 may be a forward-viewing endoscope, an oblique-viewing endoscope, or a side-viewing endoscope.

Inside the camera head 13102, an optical system and a photoelectric conversion apparatus are disposed. Reflected light (observation light) from the observation target is collected to the photoelectric conversion apparatus through the optical system. The photoelectric conversion apparatus photoelectrically converts the observation light to generate an electrical signal corresponding to the observation light, or equivalently, an image signal corresponding to an observation image. The photoelectric conversion apparatuses described in the foregoing exemplary embodiments can be used as the photoelectric conversion apparatus. The image signal is transmitted to a camera control unit (CCU) 13135 as raw data.

The CCU 13135 includes a central processing unit (CPU) and a graphics processing unit (GPU) and controls the operation of the endoscope 13100 and a display device 13136 in a centralized manner. The CCU 13135 receives the image signal from the camera head 13102, and applies various types of image processing, such as development processing (demosaicing processing), for displaying an image based on the image signal to the image signal.

The display device 13136 displays the image based on the image signal subjected to the image processing performed by the CCU 13135, under control of the CCU 13135.

The light source device 13203 includes a light source such as a light-emitting diode (LED), for example, and supplies illumination light to the endoscope 13100 in capturing an image of a surgical site.

An input device 13137 is an input I/F for the endoscopic surgery system 13003. The user (operator) can input various types of information and instructions to the endoscopic surgery system 13003 via the input device 13137.

A treatment tool control device 13138 controls driving of an energy treatment tool 13112 for tissue cauterization, cutting, or sealing of blood vessels.

The light source device 13203 that supplies the endoscope 13100 with the illumination light in capturing an image of the surgical site can include a white light source including an LED, a laser light source, or a combination of these, for example. If the white light source is constituted by combining red (R), blue (B), and green (G) (RGB) laser light sources, the light source device 13203 can adjust the white balance of the captured image since the output intensity and output timing of each color (wavelength) can be controlled with high precision. In such a case, images corresponding to the R, G, and B colors can be captured in a time-division manner by irradiating the observation target with the respective laser beams from the RGB laser light sources in a time-division manner and controlling the driving of the image sensor of the camera head 13102 in synchronization with the irradiation timing. According to such a method, a color image can be obtained without providing color filters on the image sensor.

The driving of the light source device 13203 can also be controlled such that the intensity of the output light changes at predetermined time intervals. By controlling the driving of the image sensor of the camera head 13102 in synchronization with the changing timing of the light intensity to obtain images in a time-division manner and combining the images, a high dynamic range image with no underexposure or overexposure can be generated.

The light source device 13203 may also be configured such that light in a predetermined wavelength band for special light observation can be supplied. For example, special light observation uses the wavelength dependence of light absorption by body tissues. Specifically, a high-contrast image of predetermined tissues, such as blood vessels in the mucosal surface layer, is captured by irradiating the mucosal surface layer with narrow-band light compared to the illumination light used in normal observation (i.e., white light). As another example of special light observation, fluorescence observation may be performed to obtain images based on fluorescence caused by excitation light irradiation. In fluorescence observation, fluorescence images can be obtained by irradiating body tissues with excitation light and observing fluorescence from the body tissues, or by locally injecting a reagent such as indocyanine green (ICG) into the body tissues and irradiating the body tissues with excitation light corresponding to the fluorescence wavelength of the reagent. The light source device 13203 can be configured to be capable of supplying narrow-band light and/or excitation light for such special light observation.

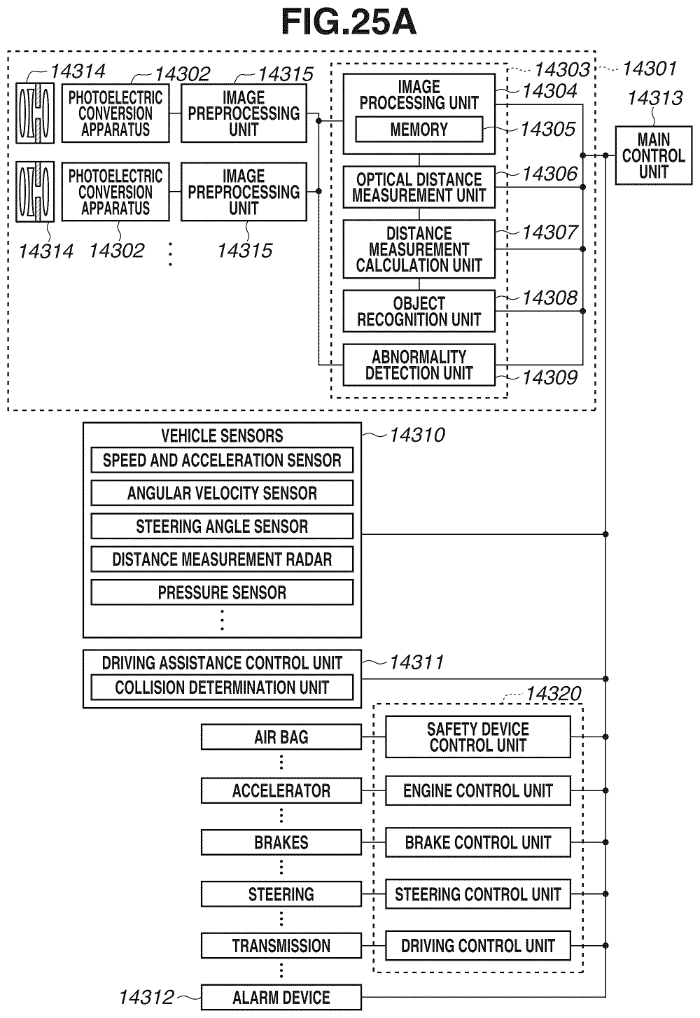

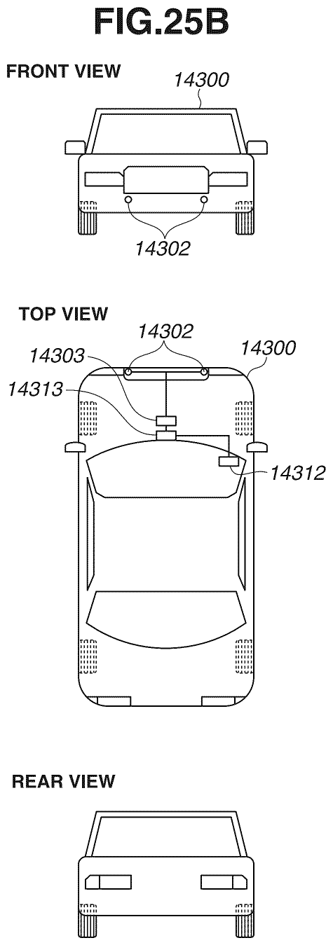

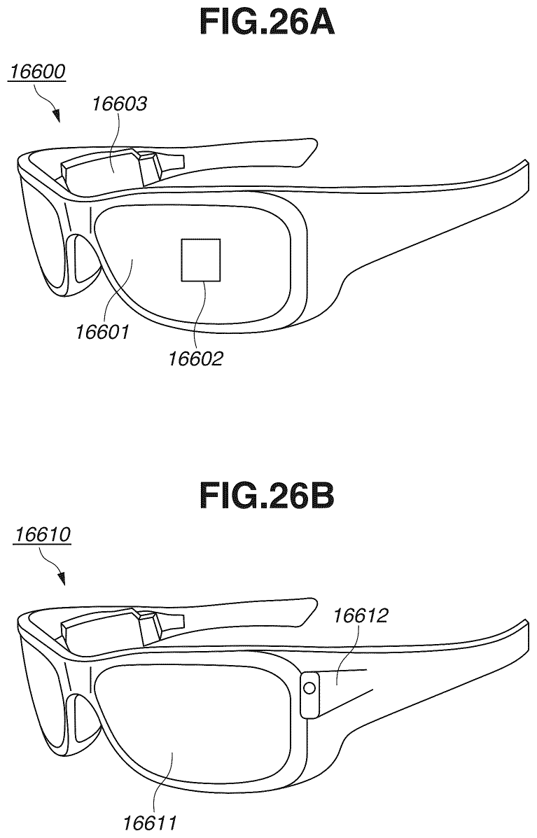

A photoelectric conversion system and a moving body according to a tenth exemplary embodiment will be described with reference to FIGS. 25A, 25B, 26A, and 26B. FIGS. 25A and 25B are schematic diagrams illustrating a configuration example of the photoelectric conversion system and the moving body according to the present exemplary embodiment. In the present exemplary embodiment, an on-vehicle camera will be described as an example of the photoelectric conversion system.

FIGS. 25A and 25B illustrate an example of a vehicle system and an imaging photoelectric conversion system mounted thereon. A photoelectric conversion system 14301 includes photoelectric conversion apparatuses 14302, image preprocessing units 14315, an integrated circuit 14303, and optical systems 14314. The optical systems 14314 form optical images of an object on the photoelectric conversion apparatuses 14302. The photoelectric conversion apparatuses 14302 convert the optical images of the object formed by the optical systems 14314 into electrical signals. The photoelectric conversion apparatuses 14302 are ones according to any of the foregoing exemplary embodiments. The image preprocessing units 14315 perform predetermined signal processing on the signals output from the photoelectric conversion apparatuses 14302. The functions of the image preprocessing units 14315 may be incorporated into the photoelectric conversion apparatuses 14302. The photoelectric conversion system 14301 includes at least two sets of an optical system 14314, a photoelectric conversion apparatus 14302, and an image preprocessing unit 14315. The outputs from the image preprocessing units 14315 of the respective sets are input to the integrated circuit 14303.

The integrated circuit 14303 is an integrated circuit for imaging system applications. The integrated circuit 14303 includes an image processing circuit 14304 including a memory 14305, an optical distance measurement unit 14306, a distance measurement calculation unit 14307, an object recognition unit 14308, and an abnormality detection unit 14309. The image processing unit 14304 performs image processing such as development processing and defect correction on the output signals of the image preprocessing units 14315. The memory 14305 temporarily stores captured images and stores the positions of defective imaging pixels. The optical distance measurement unit 14306 performs focusing and distance measurement on the object. The distance measurement calculation unit 14307 calculates distance measurement information from a plurality of pieces of image data acquired by the plurality of photoelectric conversion apparatuses 14302. The object recognition unit 14308 recognizes objects such as cars, roads, road signs, and people. The abnormality detection unit 14309 notifies the main control unit 14313 of an abnormality if an abnormality of the photoelectric conversion apparatuses 14302 is detected.

The integrated circuit 14303 may be implemented by dedicatedly designed hardware, by software modules, or by a combination of these. A field programmable gate array (FPGA) or an application specific integrated circuit (ASIC) may be used for implementation. The integrated circuit 14303 may be implemented by a combination of these.

The main control unit 14313 supervises and controls the operation of the photoelectric conversion system 14301, vehicle sensors 14310, and control units 14320. The vehicle system does not necessarily need to include the main control unit 14313. The photoelectric conversion system 14301, the vehicle sensors 14310, and the control units 14320 may include respective communication I/Fs and transmit and receive control signals to/from each other via the communication I/Fs (for example, based on a control area network [CAN] standard).

The integrated circuit 14303 has a function of transmitting control signals and setting values to the photoelectric conversion apparatuses 14302 by receiving the control signals from the main control unit 14313 or based on the initiative of its own control unit.

The photoelectric conversion system 14301 is connected to the vehicle sensors 14310 and can detect the vehicle's own driving state, such as a vehicle speed, yaw rate, and steering angle, as well as the environment outside the vehicle and the state of other vehicles and obstacles. The vehicle sensors 14310 also serve as a distance information acquisition unit for acquiring distance information about a target object. The photoelectric conversion system 14301 is also connected to a driving assistance control unit 14311 that provides various types of driving assistance, such as automatic steering, automatic cruising, and collision avoidance functions. In particular, as for a collision determination function, the driving assistance control unit 14311 estimates a collision and determines the presence or absence of a collision with other vehicles and obstacles based on the detection results of the photoelectric conversion system 14301 and the vehicle sensors 14310. The driving assistance control unit 14311 thereby performs avoidance control when a collision is estimated or activates safety devices in the event of a collision.

The photoelectric conversion system 14301 is also connected to the alarm device 14312 that issues an alarm to the driver based on the determination result of the collision determination unit. For example, if the determination result of the collision determination unit shows a high possibility of a collision, the main control unit 14313 performs vehicle control to avoid the collision or reduce the damage by applying the brakes, releasing the accelerator, and/or reducing the engine output. The alarm device 14312 warns the user by sounding an alarm, displaying alarm information on the screen of a display unit such as a car navigation system and a meter panel, and/or vibrating the seat belt or the steering wheel.

In the present exemplary embodiment, the photoelectric conversion system 14301 captures images of the surroundings of the vehicle, such as in front or behind. FIG. 25B illustrates a layout example of the photoelectric conversion system 14301 in a case where the photoelectric conversion system 14301 captures images in front of the vehicle.

The two photoelectric conversion apparatuses 14302 are disposed on the front of a vehicle 14300. Specifically, a centerline of the vehicle 14300 along the forward-backward direction or with respect to the outer shape thereof (e.g., vehicle width) is assumed as an axis of symmetry. To acquire distance information between the vehicle 14300 and an object and determine the possibility of a collision, the two photoelectric conversion apparatuses 14302 are desirably symmetrically arranged about the axis of symmetry. The photoelectric conversion apparatuses 14302 are also desirably located to not obstruct the driver's field of view when the driver visually observes the conditions outside the vehicle 14300 from the driver's seat. The alarm device 14312 is desirably located at a position easily visible to the driver.

While the present exemplary embodiment has dealt with a control to avoid a collision with other vehicles, the photoelectric conversion system 14301 is also applicable to automatic driving control to follow another vehicle or automatic driving control to stay in the lane. Moreover, the photoelectric conversion system 14301 is not limited to vehicles, such as the own vehicle, and can be applied to moving bodies (moving apparatuses), such as a ship, an aircraft, and an industrial robot, for example. Furthermore, the photoelectric conversion system 14301 is not limited to a moving body, either, and can be widely applied to devices using object recognition, such as an intelligent transportation system (ITS).

The photoelectric conversion apparatuses 14302 according to the present exemplary embodiment may also be configured to be capable of acquiring various types of information, such as distance information.

FIG. 26A illustrates glasses 16600 (smart glasses) according to an application example of an eleventh exemplary embodiment. The glasses 16600 include a photoelectric conversion apparatus 16602. The photoelectric conversion apparatus 16602 is a photoelectric conversion apparatus according to any of the foregoing exemplary embodiments. On the backside of a lens 16601, a display device including a light emission device, such as an organic light-emitting diode (OLED) and an LED, may be disposed. There may be one or more photoelectric conversion apparatuses 16602. A plurality of types of photoelectric conversion apparatuses may be used in combination. The disposed position of the photoelectric conversion apparatus 16602 is not limited to that illustrated in FIG. 26A.

The glasses 16600 further include a control apparatus 16603. The control apparatus 16603 functions as a power supply for supplying power to the photoelectric conversion apparatus 16602 and the display device mentioned above. The control apparatus 16603 controls the operation of the photoelectric conversion apparatus 16602 and the display device. The lens 16601 includes an optical system for collecting light to the photoelectric conversion apparatus 16602.

FIG. 26B illustrates glasses 16610 (smart glasses) according to another application example. The glasses 16610 include a control apparatus 16612. The control apparatus 16612 includes a photoelectric conversion apparatus corresponding to the photoelectric conversion apparatus 16602, and a display device. A lens 16611 includes the photoelectric conversion apparatus included in the control apparatus 16612 and an optical system for projecting light emitted from the display device, whereby an image is projected on the lens 16611. The control apparatus 16612 functions as a power supply for supplying power to the photoelectric conversion apparatus and the display device and controls the operation of the photoelectric conversion apparatus and the display device. The control apparatus 16612 may include a line of sight detection unit that detects the line of sight of the wearer (user). The line of sight may be detected using infrared rays. An infrared light emitting unit emits infrared rays toward the user's eyeball gazing at a displayed image. An imaging unit including a light receiving element detects reflection of the emitted infrared rays from the eyeball, whereby a captured image of the eyeball is obtained. A drop in image quality can be reduced by providing a reduction unit configured to reduce light from the infrared light emitting unit to the display unit in a plan view.

The user's line of sight to the displayed image is detected from the captured image of the eyeball obtained by the infrared imaging. Any conventional technique can be applied to the line of sight detection using the captured image of the eyeball. For example, a line of sight detection method based on a Purkinje image formed by the reflection of the illumination light on the cornea can be used.

More specifically, line of sight detection processing based on the pupil-cornea reflection method is performed. The user's line of sight is detected by calculating a line of sight vector indicating the direction (rotation angle) of the eyeball based on the pupil image and the Purkinje image included in the captured image of the eyeball, using the pupil-cornea reflection method.

The display device according to the present exemplary embodiment may include a photoelectric conversion apparatus including a light receiving element and control the image displayed by the display device based on the user's line of sight information from the photoelectric conversion apparatus.

Specifically, the display device determines a first field of view region at which the user is gazing and a second field of view region other than the first field of view region, based on the line of sight information. The first field of view region and the second field of view region may be determined by a control apparatus of the display device. The first and second fields of view regions determined by an external control apparatus may be received. The display resolution of the first field of view region may be controlled to be higher than that of the second field of view region on the display area of the display device. In other words, the resolution of the second field of view region may be made lower than that of the first field of view region.

The display area may include a first display region and a second display region different from the first display region, and a region of higher priority may be determined between the first and second display regions based on the line of sight information. The first and second display regions may be determined by the control apparatus of the display device. The first and second display regions determined by an external control apparatus may be received. The resolution of the region of higher priority may be controlled to be higher than that of the region other than the region of higher priority. In other words, the resolution of the region of relatively low priority may be lowered.

The first field of view region or the region of higher priority may be determined using artificial intelligence (AI). The AI may be a model that is configured to estimate the angle of the line of sight and the distance to an object on the line of sight from the eyeball image, with eyeball images and the actual viewing directions of the eyeballs in the images as training data. Such an AI program may be included in the display device, the photoelectric conversion apparatus, or an external apparatus. If the AI program is included in the external apparatus, the estimation results are transmitted to the display device via communication.

If display control is performed based on visual detection, smart glasses further including a photoelectric conversion apparatus for capturing an image of the outside can be suitably applied. The smart glasses can display the captured external information in real time.

### OTHER EXEMPLARY EMBODIMENTS

While the exemplary embodiments have been described above, the present invention is not limited to the exemplary embodiments, and various changes and modifications can be made. Moreover, the exemplary embodiments are mutually applicable. More specifically, a part of one exemplary embodiment can be replaced with a part of another exemplary embodiment. A part of one exemplary embodiment can also be added to a part of another exemplary embodiment. A part of an exemplary embodiment can also be deleted.

The present invention is not limited to the foregoing exemplary embodiments, and various changes and modifications can be made without departing from the spirit and scope of the present invention. The following claims are therefore appended to make the scope of the present invention public.

According to an exemplary embodiment of the present invention, a wiring configuration that solves issues resulting from a high wiring density of an APD sensor can be proposed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A photoelectric conversion apparatus comprising:
a first substrate including a first semiconductor layer and a first wiring structure, the first semiconductor layer including a plurality of photoelectric conversion units, the first wiring structure including at least one wiring layer; and
a second substrate including a second semiconductor layer and a second wiring structure, the second semiconductor layer including a plurality of pixel circuits disposed to correspond to each of the plurality of photoelectric conversion units, respectively, the second wiring structure including a plurality of wiring layers,
wherein each of the plurality of photoelectric conversion units includes an avalanche photodiode,
wherein the first substrate and the second substrate are stacked such that the first wiring structure and the second wiring structure are located between the first semiconductor layer and the second semiconductor layer,
wherein the first wiring structure or the second wiring structure includes a pad electrode configured to supply a voltage to the avalanche photodiode,
wherein the plurality of wiring layers of the second wiring structure includes a wiring layer where first wiring configured to supply a power supply voltage to the plurality of pixel circuits is disposed and an area occupied by the first wiring is largest among the plurality of wiring layers, and a wiring layer group where the first wiring is disposed, the wiring layer group being located between the wiring layer where the area occupied by the first wiring is the largest among the plurality of wiring layers and the second semiconductor layer, and
wherein, in a plan view, the first wiring is configured to connect both ends of a region in a first direction and both ends of the region in a second direction intersecting the first direction by combination of the wiring layer group, the region including each of the plurality of pixel circuits.

2. The photoelectric conversion apparatus according to claim 1,
wherein the wiring layer group includes a first wiring layer and a second wiring layer,
wherein, in the plan view, the first wiring on the first wiring layer is not connected to both ends of the region in the first direction, and
wherein, in the plan view, the first wiring on the second wiring layer is not connected to both ends of the region in the second direction.

3. The photoelectric conversion apparatus according to claim 2, wherein, in the plan view, the first wiring on the first wiring layer is not connected to both ends of the region in the second direction.

4. The photoelectric conversion apparatus according to claim 2,
wherein, in the plan view, the first wiring on the first wiring layer is connected to both ends of the region in the second direction, and
wherein, in the plan view, the first wiring on the second wiring layer is connected to both ends of the region in the first direction.

5. The photoelectric conversion apparatus according to claim 1,
wherein the wiring layer group includes a first wiring layer, a second wiring layer, and a third wiring layer,
wherein, in the plan view, the first wiring on the first wiring layer is connected to both ends of the region in the first direction, and
wherein, in the plan view, the first wiring is connected to both ends of the region in the second direction by combination of the second wiring layer and the third wiring layer.

6. The photoelectric conversion apparatus according to claim 5,
wherein, in the plan view, the first wiring on the first wiring layer is not connected to both ends of the region in the second direction,
wherein, in the plan view, the first wiring on the second wiring layer is not connected to both ends of the region in the first direction and the second direction, and
wherein, in the plan view, the first wiring on the third wiring layer is not connected to both ends of the region in the first direction and the second direction.

7. A photoelectric conversion apparatus comprising:
a first substrate including a first semiconductor layer and a first wiring structure, the first semiconductor layer including a plurality of photoelectric conversion units, the first wiring structure including at least one wiring layer; and
a second substrate including a second semiconductor layer and a second wiring structure, the second semiconductor layer including a plurality of pixel circuits disposed to correspond to each of the plurality of photoelectric conversion units, respectively, the second wiring structure including a plurality of wiring layers,
wherein each of the plurality of photoelectric conversion units includes an avalanche photodiode,
wherein the first substrate and the second substrate are stacked such that the first wiring structure and the second wiring structure are located between the first semiconductor layer and the second semiconductor layer,
wherein the first wiring structure or the second wiring structure includes a pad electrode configured to supply a voltage to the avalanche photodiode,
wherein the plurality of wiring layers of the second wiring structure includes a wiring layer group where first wiring configured to supply a power supply voltage to the plurality of pixel circuits is disposed,
wherein the wiring layer group includes a first wiring layer and a second wiring layer,
wherein, in a plan view, the first wiring on the first wiring layer is not connected to at least both ends of a region in a first direction, the region including each of the plurality of pixel circuits,
wherein, in the plan view, the first wiring on the second wiring layer is not connected to at least both ends of the region in a second direction, and
wherein, in the plan view, the first wiring is configured to be connected to both ends of the region in the first direction and both ends of the region in the second direction by combination of the first wiring layer and the second wiring layer.

8. The photoelectric conversion apparatus according to claim 1, the power supply voltage supplied by the first wiring is applied to the avalanche photodiode.

9. The photoelectric conversion apparatus according to claim 1, comprising a wiring layer where second wiring configured to supply a power supply voltage having a value different from a value of the power supply voltage supplied by the first wiring is disposed and an area occupied by the second wiring is largest among the plurality of wiring layers,
wherein the wiring layer group includes the second wiring and is located between the wiring layer where the area occupied by the second wiring is the largest among the plurality of wiring layers and the second semiconductor layer,
wherein, in the plan view, the second wiring is configured to connect both ends of the region in the first direction and both ends of the region in the second direction by combination of the wiring layer group.

10. The photoelectric conversion apparatus according to claim 9, wherein the power supply voltage supplied by the second wiring is applied to the plurality of pixel circuits.

11. The photoelectric conversion apparatus according to claim 1, wherein the plurality of pixel circuits is arranged in a mirror symmetrical arrangement.

12. The photoelectric conversion apparatus according to claim 1,
wherein the plurality of pixel circuits includes a pixel circuit of a first pixel and a pixel circuit of a second pixel,
wherein the pixel circuit of the first pixel includes a first counter circuit,
wherein the pixel circuit of the second pixel includes a second counter circuit,
wherein the first pixel and the second pixel are located to adjoin each other, and
wherein the first counter circuit and the second counter circuit are located to adjoin each other.

13. The photoelectric conversion apparatus according to claim 1,
wherein the plurality of pixel circuits includes a pixel circuit of a first pixel and a pixel circuit of a second pixel,
wherein the pixel circuit of the first pixel includes a first quenching element,
wherein the first pixel and the second pixel are located to adjoin each other, and
wherein the first quenching element is located at a corner of a region where the pixel circuit of the first pixel is disposed.

14. The photoelectric conversion apparatus according to claim 1,
wherein the plurality of pixel circuits includes a pixel circuit of a first pixel and a pixel circuit of a second pixel,
wherein the pixel circuit of the first pixel includes a first quenching element,
wherein the pixel circuit of the second pixel includes a second quenching element,
wherein the first pixel and the second pixel are located to adjoin each other, and
wherein the first quenching element and the second quenching element are located to adjoin each other.

15. The photoelectric conversion apparatus according to claim 1,
wherein the plurality of pixel circuits includes a pixel circuit of a first pixel and a pixel circuit of a second pixel,
wherein the pixel circuit of the first pixel includes a first waveform shaping circuit,
wherein the pixel circuit of the second pixel includes a second waveform shaping circuit,
wherein the first pixel and the second pixel are located to adjoin each other, and
wherein the first waveform shaping circuit and the second waveform shaping circuit are located to adjoin each other.

16. The photoelectric conversion apparatus according to claim 15,
wherein the pixel circuit of the first pixel includes a first quenching element, and
wherein the first waveform shaping circuit and the first quenching element are located to adjoin each other.

17. The photoelectric conversion apparatus according to claim 12, wherein the pixel circuit of the first pixel and the pixel circuit of the second pixel are arranged in a mirror symmetrical arrangement.

18. The photoelectric conversion apparatus according to claim 1,
wherein the pad electrode is included in the first wiring structure, and
wherein another pad electrode configured to supply a voltage to the avalanche photodiode along with the pad electrode is included in the first wiring structure.

19. The photoelectric conversion apparatus according to claim 18,
wherein the avalanche photodiode includes an anode and a cathode,
wherein the pad electrode is configured to supply a potential to the anode, and
wherein the other pad electrode is configured to supply a potential to the cathode.

20. The photoelectric conversion apparatus according to claim 1,
wherein the pad electrode is included in the first wiring structure, and
wherein another pad electrode configured to supply a voltage to the avalanche photodiode along with the pad electrode is included in the second wiring structure.

21. The photoelectric conversion apparatus according to claim 20,
wherein the avalanche photodiode includes an anode and a cathode,
wherein the pad electrode is configured to supply a potential to the anode, and
wherein the other pad electrode is configured to supply a potential to the cathode.

22. The photoelectric conversion apparatus according to claim 1, wherein the pad electrode is included in the second wiring structure.

23. The photoelectric conversion apparatus according to claim 1,
wherein the wiring layer included in the first wiring structure includes wiring consisting mainly of copper, and
wherein the pad electrode consists mainly of aluminum.

24. A photoelectric conversion system comprising:
the photoelectric conversion apparatus according to claim 1; and
a signal processing unit configured to process a signal output from the photoelectric conversion apparatus.

25. A moving body comprising:
the photoelectric conversion apparatus according to claim 1;
a distance information acquisition unit configured to acquire distance information about an object from distance measurement information based on a signal from the photoelectric conversion apparatus; and
a control unit configured to control the moving body based on the distance information.
